(19) United States
(12) Patent Application Publication
(10) Pub. No.: US 2024/0122050 A1
(43) Pub. Date: Apr. 11, 2024

(54) DISPLAY MODULE AND MANUFACTURING METHOD FOR THE SAME

(71) Applicant: Samsung Display Co., Ltd., Yongin-si (KR)

(72) Inventors: SEUNGJAE KANG, Yongin-si (KR); KIYONG KIM, Yongin-si (KR); SEOUNGBUM PYOUN, Yongin-si (KR)

(73) Assignee: Samsung Display Co., Ltd., Yongin-si (KR)

(21) Appl. No.: 18/476,454

(22) Filed: Sep. 28, 2023

(30) Foreign Application Priority Data
Oct. 5, 2022 (KR) 10-2022-0127119

(51) Int. Cl. H10K 59/80; H10K 59/12; H10K 59/131

(52) U.S. Cl. CPC H10K 59/8794; H10K 59/1201; H10K 59/131

(57) ABSTRACT

A display module includes a base including a display region and a non-display region, pixels disposed in the display region, a driver disposed in the non-display region and electrically connected to the pixels to provide a driving signal, signal pads disposed in the non-display region and electrically connected to the driver, a heater overlapping the driver and disposed below the signal pads, and a heating signal pad electrically connected to the heater.

### CROSS-REFERENCE TO RELATED APPLICATION(S)

This U.S. non-provisional patent application claims priority to and benefits of Korean Patent Application No. 10-2022-0127119 under 35 U.S.C. § 119, filed on Oct. 5, 2022 in the Korean Intellectual Property Office, the entire contents of which are incorporated herein by reference.

### BACKGROUND

### 1. Technical Field

The disclosure relates to a display module which displays an image and to which a driving unit may be bonded, and a method for manufacturing the same.

### 2. Description of the Related Art

Multimedia electronic devices such as televisions, mobile phones, tablets, navigation systems, and game machines may include a display module for displaying an image. The display module may include circuit lines and electronic elements connected to the circuit lines and may be electrically bonded to a driving unit configured to provide an electrical signal required for displaying an image.

However, a process of bonding the driving unit or the electronic elements to the display module may require a high-temperature environment, and other components of the display module may be damaged in the process.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display module including a heating unit (heater) that uniformly and precisely heats the inside of a region in which a driving unit (driver) is bonded to a display panel.

The disclosure also provides a method for manufacturing a display module which prevents components of the display module from being damaged by a high-temperature external bonding device by lowering the temperature of the external bonding device in a process of bonding a driving unit to a display panel.

An embodiment provides a display module that may include a base including a display region and a non-display region, pixels disposed in the display region; a driver disposed in the non-display region and electrically connected to the pixels to provide a driving signal, signal pads disposed in the non-display region and electrically connected to the driver, a heater overlapping the driver and disposed below the signal pads, and a heating signal pad electrically connected to the heater.

In an embodiment, the heater may include a first conductive pattern disposed on the base. The first conductive pattern may include first line portions extending in a first direction, and second line portions integrally connected to the first line portions on a same layer and extending in a second direction intersecting the first direction.

In an embodiment, the heater may further include a second conductive pattern disposed on the first conductive pattern. The second conductive pattern may include third line portions extending in the first direction, and fourth line portions integrally connected to the third line portions on a same layer and extending in the second direction.

In an embodiment, the first conductive pattern and the second conductive pattern may be electrically insulated from each other.

In an embodiment, the heater may include a first conductive pattern disposed on the base and a second conductive pattern disposed on the first conductive pattern. The first conductive pattern may include a first pattern connected to the heating signal pad, and a plurality of second patterns spaced apart from the first pattern. The second conductive patterns may include third patterns which contact adjacent second patterns among the plurality of second patterns and connect the adjacent second patterns to each other.

In an embodiment, the third patterns may contain a material different from that of the plurality of second patterns.

In an embodiment, the heating signal pad may include a first heating signal pad and a second heating signal pad spaced apart from each other. The heater may include a first conductive pattern connected to the first heating signal pad and a second conductive pattern connected to the second heating signal pad and disposed on the first conductive pattern.

In an embodiment, the first conductive pattern may include a first planar portion overlapping the signal pads, and the second conductive pattern may include a second planar portion contacting the first planar portion.

In an embodiment, the first planar portion and the second planar portion may contain different materials from each other.

In an embodiment, pattern openings passing through the second conductive pattern may be defined in the second planar portion. The pattern openings may be disposed in a direction.

In an embodiment, the first heating signal pad and the second heating signal pad may be disposed on different layers.

In an embodiment, each of the first heating signal pad and the second heating signal pad may be disposed on a layer different from that of the signal pads.

In an embodiment, the base may include a base layer that provides a base surface on which the heater and the signal pads are disposed. A portion of the base layer, which corresponds to a region between the display region and the driver in a plan view, may be bent with respect to a bending axis.

In an embodiment, the base may include a base layer that provides a base surface on which the pixels are disposed, and a flexible circuit board disposed on the base layer. The driver, the signal pads, the heater, and the heating signal pad may be disposed on the flexible circuit board. The flexible circuit board may be bent toward a rear surface of the base layer.

In an embodiment, each of the pixels may include a transistor including a gate electrode, an upper electrode overlapping the gate electrode, a light-emitting element electrically connected to the transistor, and a connection electrode electrically connecting the transistor and the light-emitting element to each other. The heater may include a conductive pattern disposed on the same layer as at least one of the gate electrode, the upper electrode, and the connection electrode.

In an embodiment, the display module may further include a conductive adhesive member disposed between the signal pads and the driver to electrically connect the signal pads and the driver to each other.

In an embodiment, a display module may include a base layer including a display region and a driver bonding region spaced apart from the display region, pixels disposed on the display region, signal lines electrically connected to the pixels and extending from the display region toward the driver bonding region, signal pads disposed on the driver bonding region and electrically connected to the signal lines, a heater overlapping the signal pads, and a heating signal pad electrically connected to the heater. The heating signal pad and the signal pads may be electrically insulated from each other.

In an embodiment, the display module may further include connection pads spaced apart from the driver bonding region in a first direction and respectively connected to corresponding signal pads among the signal pads. The heating signal pad and the connection pads may be disposed in a second direction intersecting the first direction.

In an embodiment, a method for manufacturing a display module may include providing the display module including a heater, a heating signal pad electrically connected to the heater, and signal pads disposed on the heater and spaced apart from the heating signal pad, providing a conductive adhesive member on the signal pads, providing a driver on the conductive adhesive member, and heating the conductive adhesive member to electrically connect the signal pads and the driver to each other. The heating of the conductive adhesive member may include applying a current to the heating signal pad to heat the heater.

In an embodiment, the electrical connection of the signal pads to the driver may further include providing an external bonding device on the driver to apply pressure to the conductive adhesive member.

### BRIEF DESCRIPTION OF THE DRAWINGS

The accompanying drawings are included to provide a further understanding of the disclosure, and are incorporated in and constitute a part of this specification. The drawings illustrate embodiments and, together with the description, serve to explain principles of the disclosure. In the drawings:

FIG. 1 is a schematic perspective view of an electronic device according to an embodiment;

FIG. 2 is an exploded schematic perspective view of the electronic device according to an embodiment;

FIGS. 3A and 3B are schematic plan views of a display module according to an embodiment;

FIG. 4 is a schematic cross-sectional view of a display panel according to an embodiment;

FIGS. 5A to 5C are schematic plan views of a heating unit (heater) according to an embodiment;

FIGS. 6A and 6B are schematic plan views of a heating unit according to an embodiment;

FIG. 7 is a schematic cross-sectional view of a display module according to an embodiment; and

FIGS. 8 and 9 are schematic cross-sectional views illustrating a step of a method for manufacturing a display module according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In this specification, it will be understood that when an element (or region, layer, portion, part, etc.) is referred to as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of elements may be exaggerated for effective description of the technical contents.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.” “×”

It will be understood that, although the terms “first,” “second,” etc. may be used herein to describe various elements, these elements should not be limited by these terms. These terms are only used to distinguish one element from another element. For example, a first element could be termed a second element without departing from the scope of the disclosure. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

It will be understood that the terms “comprise,” “include,” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

It will be understood that the terms “connected to” or “coupled to” may include a physical and/or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

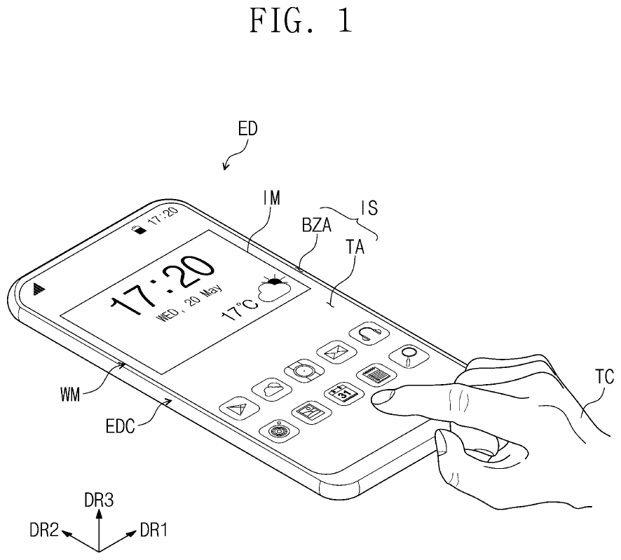

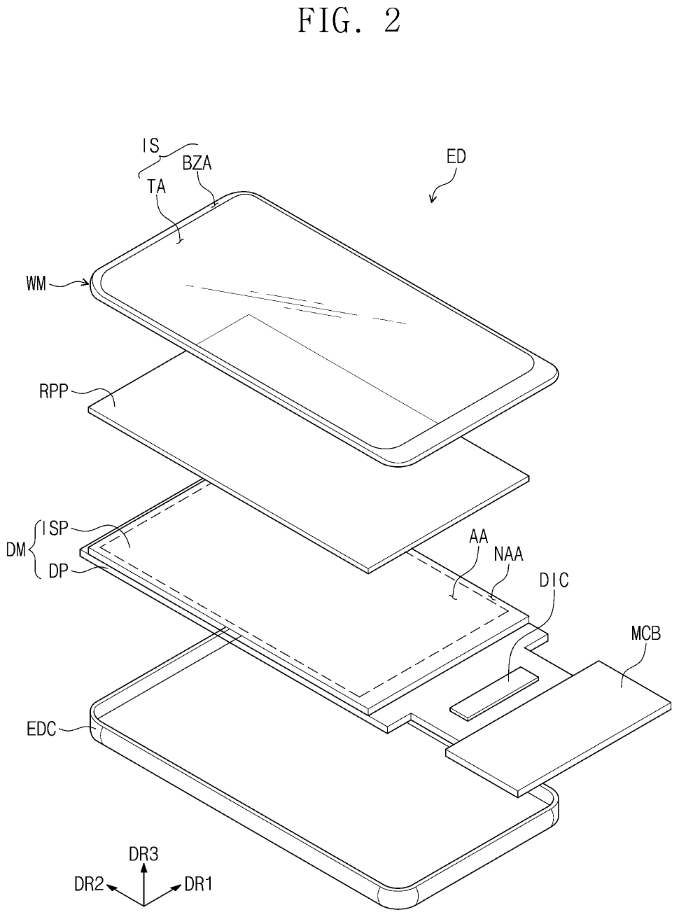

FIG. 1 is a schematic perspective view of an electronic device ED according to an embodiment. FIG. 2 is an exploded schematic perspective view of the electronic device ED according to an embodiment.

Referring to FIGS. 1 and 2, the electronic device ED may be activated according to an electrical signal, display an image IM, and sense an external input TC. For example, the electronic device ED may include devices such as monitors, mobile phones, tablets, navigation systems, and game machines. However, embodiments of the electronic device ED are just examples and the electronic device ED is not limited thereto. In an embodiment, a mobile phone is illustrated as an example of the electronic device ED.

When viewed in a plan, the electronic device ED may have a rectangular shape having short sides extending in a first direction DR1 and long sides extending in a second direction DR2 crossing (intersecting) the first direction DR1. However, the disclosure is not limited thereto, and the electronic device ED may have various shapes such as a circular shape and a polygonal shape in plan view.

In this embodiment, a third direction DR3 may be defined as a direction perpendicular to a plane defined by the first and second directions DR1 and DR2. The front surface (or upper surface) and the rear surface (or lower surface) of each member constituting the electronic device ED may be opposed to each other in the third direction DR3, and the normal direction of each of the front and rear surfaces may be substantially parallel to the third direction DR3. The separation distance between the front and rear surfaces defined along the third direction DR3 may correspond to a thickness of the member.

In this specification, the expression “when viewed in a plan” may be defined as a state viewed from the third direction DR3. In this specification, the expression “in cross-sectional view” may be defined as a state viewed from the first direction DR1 or the second direction DR2. Directions indicated by the first, second, and third directions DR1, DR2, and DR3 are relative concepts and may be converted into other directions.

The electronic device ED may be rigid or flexible. The term “flexible” means a property of being bendable, and the structure of a flexible electronic device ED may include everything from a completely foldable structure to a structure that can be bent to the level of several nanometers. For example, the flexible electronic device ED may include a curved device or a foldable device.

The electronic device ED may display the image IM through a display surface IS parallel to each of the first and second directions DR1 and DR2. The image IM may include a still image as well as a dynamic image. FIG. 1 illustrates a clock and icons as an example of the image IM.

The display surface IS of the electronic device ED may include only a flat surface or may further include a curved surface bent from at least one side of the flat surface. The display surface IS may correspond to the front surface of the electronic device ED and the front surface of the window WM as well. Hereinafter, the front surface of the window WM will be described by using the same reference numeral as the display surface IS of the electronic device ED.

The electronic device ED according to an embodiment may sense the external input TC applied from the outside. The external input TC may include various types of inputs such as force, pressure, temperature, and/or light. In an embodiment, the external input TC is illustrated as a user's hand applied to the front surface of the electronic device ED. However, this is illustrated as an example, and the external input TC may include a touch by a pen or an input, such as hovering, applied close to the electronic device ED.

The electronic device ED may sense a user's input through the display surface IS defined on the front side thereof and respond to the sensed input signal. However, the region of the electronic device ED, which senses the external input TC, is not limited to the front surface of the electronic device ED and may be changed according to the structure of the electronic device ED. For example, the electronic device ED may sense a user's input applied to the side or rear surface of the electronic device ED.

The electronic device ED may include the window WM, an anti-reflection layer RPP, a display module DM, and a case EDC. The window WM and the case EDC may be coupled to each other to constitute the exterior of the electronic device ED.

The window WM may be disposed on the display module DM and the anti-reflection layer RPP. The window WM may cover the display module DM and the anti-reflection layer RPP and protect the components of the electronic device ED from external impacts and scratches.

The window WM may contain an optically transparent insulating material. For example, the window WM may contain glass or a synthetic resin as a base film. The window WM may have a single-layered or multi-layered structure. For example, the window WM may include plastic films bonded to each other by an adhesive or a glass film and a plastic film bonded to each other by an adhesive. The window WM may further include functional layers, such as an anti-fingerprint layer, a phase control layer, and a hard coating layer, which are disposed on the base film.

As described above, the front surface IS of the window WM may correspond to the front surface of the electronic device ED. The front surface IS of the window WM may include a transmission region TA and a bezel region BZA.

The transmission region TA may be an optically transparent region. The transmission region TA may transmit the image IM output from the display module DM. Accordingly, a user may visually recognize the image IM through the transmission region TA. In an embodiment, the transmission region TA is illustrated as a tetragonal shape with rounded corners, but the transmission region TA may have various shapes and is not limited to any one embodiment.

The bezel region BZA may have lower light transmittance than the transmission region TA. The bezel region BZA may correspond to a region in which a material having a predetermined or selected color is printed. The bezel region BZA may prevent transmission of light, thereby preventing the components of the display module DM disposed to overlap the bezel region BZA from being visually recognized from the outside.

The bezel region BZA may be adjacent to the transmission region TA. The shape of the transmission region TA may be substantially defined by the bezel region BZA. For example, the bezel region BZA may be disposed outside the transmission region TA to surround the transmission region TA. However, this is illustrated as an example, and the bezel region BZA may be adjacent to only one side of the transmission region TA or may be disposed on a side surface of the electronic device ED, not the front side thereof. The bezel region BZA may be omitted.

The display module DM may be disposed between the window WM and the case EDC. The display module DM may display the image IM according to an electrical signal and transmit and receive information on the external input TC. The image IM may be displayed on the front surface of the display module DM. The front surface of the display module DM may include an active region AA and a peripheral region NAA adjacent to the active region AA.

The active region AA may be activated according to an electrical signal. The active region AA may be a region in which the image IM is displayed and the external input TC is sensed as well. However, this is just an example, and the region in which the image IM is displayed and the region in which the external input TC is sensed may be separated from each other in the active region AA, and such additional embodiments are within the scope of the disclosure. The active region AA may overlap at least a portion of the transmission region TA. Accordingly, the image IM output from the active region AA may be visually recognized by a user through the transmission region TA, and the user may provide the external input TC to the active region AA through the transmission region TA.

The peripheral region NAA may be adjacent to the active region AA. For example, the peripheral region NAA may surround the active region AA. However, the disclosure is not limited thereto, and the peripheral region NAA may be defined in various shapes. A driving circuit, a driving line, a pad, and the like for driving the active region AA may be disposed in the peripheral region NAA. The peripheral region NAA may overlap at least a portion of the bezel region BZA, and the bezel region BZA may prevent the components disposed in the peripheral region NAA from being visually recognized from the outside.

The display module DM may include a display panel DP and an input sensing unit ISP. The display panel DP may output the image IM, and the input sensing unit ISP may obtain the coordinate information of the external input TC.

The display panel DP according to an embodiment may be a light-emitting display panel and is not particularly limited thereto. For example, the display panel DP may be an organic light-emitting display panel, an inorganic light-emitting display panel, or a quantum dot light-emitting display panel. The light-emitting layer of the organic light-emitting display panel may contain an organic light-emitting material, and the light-emitting layer of the inorganic light-emitting display panel may contain an inorganic light-emitting material. The light-emitting layer of the quantum dot light-emitting display panel may contain quantum dots and quantum rods. Hereinafter, the display panel DP will be described as an organic light-emitting display panel.

The input sensing unit ISP may be disposed on the display panel DP. For example, the input sensing unit ISP may be disposed directly on the display panel DP. In an embodiment, the expression “the input sensing unit ISP may be disposed directly on the display panel DP” means that the input sensing unit ISP is formed on the display panel DP through a continuous process so that the input sensing unit ISP and the display panel DP are coupled to each other without a separate adhesive layer. However, the disclosure is not limited thereto, and the input sensing unit ISP may be coupled to the display panel DP by an adhesive layer.

The input sensing unit ISP may be driven in various ways to sense the external input TC applied from the outside of the electronic device ED. For example, the input sensing unit ISP may operate in a capacitive method, a resistive film method, an infrared method, a sound wave method, a pressure method, and/or the like, but the disclosure is not limited to any one method.

A driving unit (driver) DIC may be mounted on the display panel DP. The driving unit DIC may include driving elements, for example, a data driving circuit, for driving the pixel of the display panel DP or the input sensing unit ISP. The driving unit DIC may be a driving chip provided in the form of an integrated circuit chip in the peripheral region NAA. However, the disclosure is not limited thereto, and the driving unit DIC may be mounted on a flexible circuit board connected to the display panel DP. This will be explained in detail later.

The display module DM may further include a main circuit board MCB electrically connected to the display panel DP and the input sensing unit ISP. The main circuit board MCB may be disposed on a side of the display panel DP and connected to the display panel DP. The main circuit board MCB may generate an electrical signal to be provided to the display panel DP and the input sensing unit ISP, or receive a signal generated from the input sensing unit ISP to calculate a result value including the information on the sensed position and intensity of the external input TC.

The main circuit board MCB may be directly coupled to the display panel DP so that it can be electrically connected to the display panel DP and the input sensing unit ISP. However, the disclosure is not limited thereto, and the main circuit board MCB may be electrically connected to the display panel DP and the input sensing unit ISP through the flexible circuit board connected to the display panel DP or the input sensing unit ISP. The main circuit board MCB may be electrically connected to another electronic module of the electronic device ED.

A region of the display panel DP corresponding to a region between the active region AA and the region in which the driving unit DIC is disposed may be bent. For example, the region of the display panel DP may be bent with respect to a bending axis extending in the first direction DR1. Accordingly, the driving unit DIC and the main circuit board MCB may be disposed on the rear surface of the display panel DP corresponding to the active region AA. However, the disclosure is not limited thereto, and the driving unit DIC may be mounted on a flexible circuit board, and an end and another end of the flexible circuit board may be respectively connected to the display panel DP and the main circuit board MCB. The flexible circuit board may be bent toward the rear surface of the display panel DP with respect to a bending axis extending in a direction.

The anti-reflection layer RPP may be disposed between the display module DM and the window WM. The anti-reflection layer RPP may reduce the reflectance of external light incident from the outside of the electronic device ED.

The anti-reflection layer RPP according to an embodiment may include a retarder and a polarizer. The retarder may include a λ/2 retarder and/or a λ/4 retarder. Each of the retarder and the polarizer may be a film type or a liquid crystal coating type. The film-type polarizer may include a stretchable synthetic resin film, and the liquid crystal coating-type polarizer may include liquid crystals arranged in a predetermined or selected arrangement. Without being limited thereto, the retarder and the polarizer may be implemented as one polarizing film. The anti-reflection layer RPP may further include a protective film disposed on or below the polarizing film.

The anti-reflection layer RPP according to an embodiment may include a destructive interference structure. For example, the destructive interference structure may include a first reflective layer and a second reflective layer which are disposed on different layers. First reflected light reflected from the first reflective layer and second reflected light reflected from the second reflective layer may be destructively interfered with each other, and accordingly, the anti-reflection layer RPP may reduce the reflectance of external light.

The anti-reflection layer RPP according to an embodiment may include color filters. The color filters may be disposed to correspond to the arrangement and light emitting colors of the pixels included in the display panel DP. The anti-reflection layer RPP may filter external light incident from the outside of the electronic device ED into a color corresponding to the light-emitting color of the pixels. The anti-reflection layer RPP may further include a black matrix adjacent to the color filters.

The anti-reflection layer RPP may be disposed directly on the display module DM. For example, the anti-reflection layer RPP may be formed on a base surface provided by the display module DM. Without being limited thereto, however, the anti-reflection layer RPP may be coupled to the display module DM by an adhesive layer.

The case EDC may be coupled to the window WM to provide an internal space for accommodating the anti-reflection layer RPP, the display module DM, and the main circuit board MCB. The case EDC may contain a material having relatively high rigidity. For example, the case EDC may include frames and/or plates made of glass, plastic, metal, or a combination thereof. The case EDC may absorb a shock applied from the outside or prevent foreign substances/moisture from entering from the outside to protect the components of the electronic device ED accommodated in the case EDC.

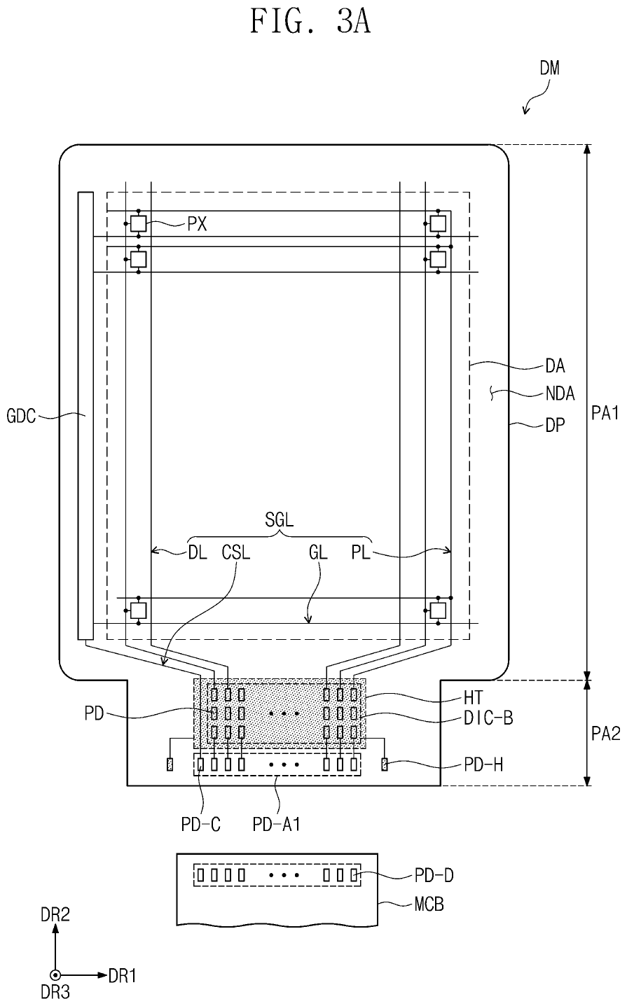

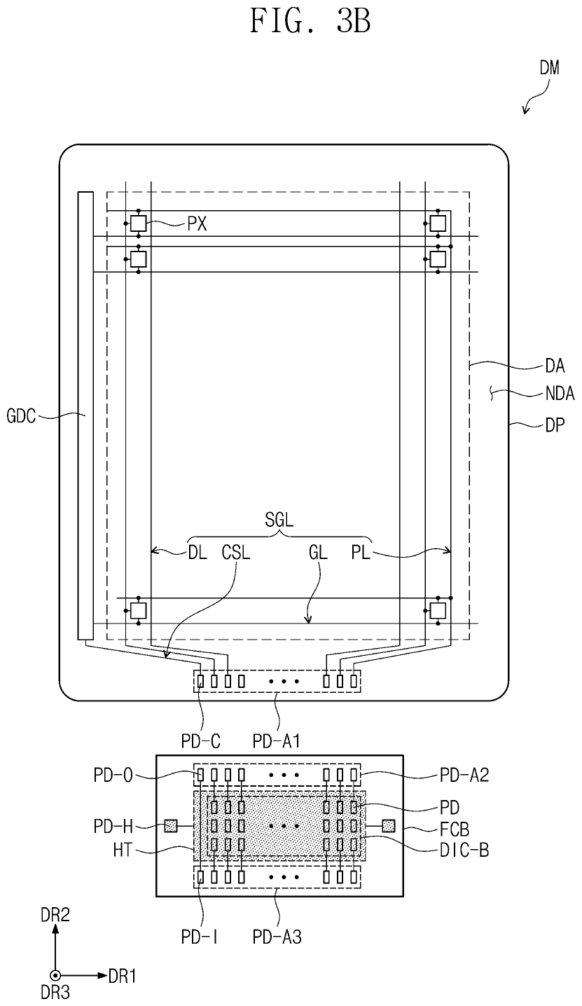

FIGS. 3A and 3B are schematic plan views of a display module DM according to an embodiment. FIGS. 3A and 3B are plan views schematically illustrating a display panel DP among the components of the display module DM.

Referring to FIG. 3A, the display panel DP may include pixels PX, a driving circuit GDC, signal lines SGL, signal pads PD, and connection pads PD-C.

The display panel DP may include a first region PA1 and a second region PA2, which are divided from each other in the second direction DR2. The second region PA2 may extend from the first region PA1 in the second direction DR2.

The first region PA1 may include a display region DA. The display region DA may correspond to the active region AA (see FIG. 2) of the display module DM. The display region DA may be a region in which light-emitting elements of the pixels PX are disposed. The pixels PX may display an image through the display region DA.

The first region PA1 excluding the display region DA and the second region PA2 may be defined as a non-display region NDA. The non-display region NDA may surround the display region DA and may be a region in which an image is not displayed. The driving circuit GDC may be disposed in the non-display region NDA corresponding to the first region PA1.

Each of the pixels PX may include a pixel driving circuit including transistors (e.g., a switching transistor and a driving transistor) and at least one capacitor, and the light-emitting element connected to the pixel driving circuit. The pixels PX may output light in response to electrical signals respectively applied to the pixels PX and display the image through the display region DA. According to an embodiment, some of the pixels PX may include a transistor disposed in the non-display region NDA, and the disclosure is not limited to any one embodiment.

The signal pads PD, the connection pads PD-C, and the driving circuit GDC for driving the pixels PX may be disposed on the non-display region NDA. The signal lines SGL disposed in the display region DA may extend to be disposed on the non-display region NDA.

The signal lines SGL may include gate lines GL, data lines DL, a power line PL, and a control signal line CSL. Each of the pixels PX may be connected to a corresponding gate line GL among the gate lines GL, a corresponding data line DL among the data lines DL, and the power line PL. The control signal line CSL may be connected to the driving circuit GDC to provide control signals.

The gate lines GL may extend in the first direction DR1 to be arranged along the second direction DR2. The data lines DL may cross the gate lines GL in plan view. The data lines DL may extend in the second direction DR2 to be arranged along the first direction DR1.

The power line PL may include a portion extending in the first direction DR1 and a portion extending in the second direction DR2. The portion of the power line PL extending in the first direction DR1 and the portion of the power line PL extending in the second direction DR2 may be disposed on different layers and connected to each other through a contact hole. Without being limited thereto, however, the portion of the power line PL extending in the first direction DR1 and the portion of the power line PL extending in the second direction DR2 may be disposed on the same layer so as to be integrally connected to each other.

At least some of the signal lines SGL may be disposed on the first region PA1 and extend toward the second region PA2. For example, each of the control signal line CSL, the data lines DL, and the power line PL may extend from the first region PA1 toward the second region PA2 so as to be connected to a corresponding signal pad PD among the signal pads PD.

The driving circuit GDC may sequentially output gate signals to the gate lines GL. The driving circuit GDC may further output another control signal to the pixels PX. The driving circuit GDC may include transistors formed through the same process as the pixel driving circuit of the pixels PX, for example, through an oxide semiconductor process, a low temperature polycrystalline silicon (LTPS) process, or a low temperature polycrystalline oxide (LTPO) process.

The signal pads PD and the connection pads PD-C may be disposed in the second region PA2 of the non-display region NDA. The region in which the signal pads PD are disposed may be defined as a driving unit (driver) bonding region DIC-B, and the region in which the connection pads PD-C are disposed may be defined as a first pad region PD-A1.

The signal pads PD may form at least one row and be arranged along the first direction DR1. FIG. 3A illustrates the signal pads PD arranged in three rows along the second direction DR2. However, the signal pads PD may be arranged in one row or in two or more rows, and the arrangement of the signal pads PD is not limited to any one embodiment.

The connection pads PD-C may be arranged along the first direction DR1. In plan view, the connection pads PD-C may be disposed closer to the lower end of the second region PA2 than the signal pads PD. Each of the connection pads PD-C may be connected to a corresponding signal pad PD among the signal pads PD through a line.

The main circuit board MCB may be rigid or flexible. For example, the main circuit board MCB may be provided as a flexible printed circuit board. The main circuit board MCB may include a timing control circuit configured to control the operation of the display panel DP. The timing control circuit may be mounted on the main circuit board MCB in the form of an integrated chip. The main circuit board MCB may include an input sensing circuit configured to control the input sensing unit ISP (see FIG. 2).

The main circuit board MCB may include driving pads PD-D. The driving pads PD-D may be arranged along the first direction DR1 to be adjacent to an end of the main circuit board MCB. The main circuit board MCB may be disposed on the second region PA2 of the display panel DP so that the driving pads PD-D respectively overlap the connection pads PD-C. The driving pads PD-D of the main circuit board MCB and the connection pads PD-C of the display panel DP, which overlap each other, may be electrically connected to each other. For example, the driving pads PD-D and the connection pads PD-C may be electrically connected to each other by using an anisotropic conductive film or an ultrasonography method. Accordingly, an electrical signal received from the main circuit board MCB may be transmitted to the signal pads PD through the connection pads PD-C.

The second region PA2 may be bent with respect to a bending axis extending in the first direction DR1. For example, the second region PA2 may be bent toward the rear surface of the display panel DP corresponding to the first region PAL. As the second region PA2 is bent, the second region PA2 may overlap the first region PA1 in plan view. As the second region PA2 is bent, the main circuit board MCB disposed on the second region PA2 may also overlap the first region PA1 in plan view.

The width of the second region PA2 in the first direction DR1 may be smaller than that of the first region PA1. For example, the second region PA2 may have a smaller width than the first region PA1 in the extending direction of the bending axis, and accordingly, the second region PA2 may be easily bent. However, this is illustrated as an example, and the width of the second region PA2 in the first direction DR1 may be substantially the same as that of the first region PAL.

The display panel DP may include a heating unit (heater) HT and a heating signal pad PD-H extending from the heating unit HT and electrically connected to the heating unit HT. The heating unit HT and the heating signal pad PD-H may be electrically insulated from the signal pads PD and the connection pads PD-C.

The heating unit HT may be disposed to overlap the driving unit bonding region DIC-B. For example, the heating unit HT may be disposed to overlap the signal pads PD. According to an embodiment, the heating unit HT may be disposed to extend to the first pad region PD-A1 and may overlap at least some of the connection pads PD-C.

Multiple heating signal pads PD-H may be provided and connected to both sides of the heating unit HT. The heating signal pad PD-H may be disposed to be parallel to the connection pads PD-C in the first direction DR1. However, the arrangement position of the heating signal pad PD-H is not limited thereto as long as a current can be independently applied to the heating signal pad PD-H.

The heating unit HT may include a conductive pattern. The conductive pattern of the heating unit HT may be connected to the heating signal pad PD-H. The resistance of the conductive pattern may vary according to the configuration, length, width, shape, and the like of the conductive pattern included in the heating unit HT. Accordingly, the conductive pattern of the heating unit HT may be designed in various ways so as to correspond to the resistance value required for the heating unit HT. The temperature of the heating unit HT to which a current is applied through the heating signal pad PD-H may be increased by the resistance of the conductive pattern of the heating unit HT, and the heating unit HT may transfer heat to the driving unit bonding region DIC-B. The embodiments of the heating unit HT will be described in detail later.

The driving unit DIC (see FIG. 2) may be mounted on the driving unit bonding region DIC-B. The driving unit DIC (see FIG. 2) may be electrically connected to the signal pads PD through a bonding process. For example, the driving unit DIC (see FIG. 2) may be electrically connected to the signal pads PD by an anisotropic conductive film. Accordingly, electrical signals received from the driving unit DIC (see FIG. 2) may be transmitted to the signal lines SGL.

In the process of mounting the driving unit DIC (see FIG. 2), a high-temperature environment may be required to connect the driving unit DIC (see FIG. 2) and the signal pads PD to each other. At this time, by applying the current to the heating unit HT to transfer heat to the driving unit bonding region DIC-B, the temperature in the driving unit bonding region DIC-B may be increased. In the process of bonding the driving unit DIC (see FIG. 2), a region requiring heat in the second region PA2 may be locally heated by the heating unit HT. For example, the temperature in the driving unit bonding region DIC-B may be increased by the heating unit HT, and a large temperature increase in a region other than the driving unit bonding region DIC-B may be prevented. Accordingly, it is possible to prevent the components of the display module DM disposed in regions other than the driving unit bonding region DIC-B from being exposed to a high-temperature environment and damaged.

Since the display panel DP includes the heating unit HT, the temperature in the driving unit bonding region DIC-B may be uniformly and precisely controlled. For example, by controlling the design of the heating unit HT or the current transmitted to the heating unit HT, as much heat as necessary may be transferred to the driving unit bonding region DIC-B, and an environment with a higher temperature than necessary may be prevented from being formed.

Since the display panel DP includes the heating unit HT, increasing a temperature by an external bonding device provided on the driving unit bonding region DIC-B may be omitted, or the degree of temperature increase by the external bonding device may be reduced. Accordingly, it is possible to prevent the components of the display module DM from being damaged by a high-temperature external bonding device. Since the second region PA2 does not need to be expanded to separate the high-temperature external bonding device from the components of the display module DM, the area of the non-display region NDA may be designed to be small. For example, as much heat as necessary may be locally transferred to the inside of the driving unit bonding region DIC-B without expanding the second region PA2 due to the heating unit HT.

An embodiment of the display module DM illustrated in FIG. 3B may include substantially the same components as an embodiment illustrated in FIG. 3A, but there may be some differences in configuration. Hereinafter, the differences will be described.

Referring to FIG. 3B, the display module DM may further include a flexible circuit board FCB, and the driving unit DIC (see FIG. 2) may be mounted on the flexible circuit board FCB instead of the display panel DP.

In an embodiment, the display panel DP may include the connection pads PD-C, and the arrangement of the signal pads PD may be omitted. The connection pads PD-C may be arranged along the first direction DR1 in the first pad region PD-A1 adjacent to the lower end of the non-display region NDA. FIG. 3B illustrates the connection pads PD-C arranged in one row, but the disclosure is not limited thereto.

At least some of the signal lines SGL may be connected to the connection pads PD-C. For example, the data lines DL, the control signal line CSL, and the power line PL may be respectively connected to the connection pads PD-C.

The flexible circuit board FCB may include first circuit connection pads PD-O, second circuit connection pads PD-I, and signal pads PD. A region in which the first circuit connection pads PD-O are disposed may be defined as a second pad region PD-A2, and a region in which the second circuit connection pads PD-I are disposed may be defined as a third pad region PD-A3. A region in which the signal pads PD are disposed may be defined as a driving unit (driver) bonding region DIC-B.

The signal pads PD may be arranged in at least one row along the first direction DR1 in the driving unit bonding region DIC-B. FIG. 3B illustrates the signal pads PD arranged in three rows along the second direction DR2. However, the signal pads PD may be arranged in fewer than or more than three rows, and the disclosure is not limited to any one embodiment.

The first circuit connection pads PD-O may be arranged along the first direction DR1 in the second pad region PD-A2 adjacent to one end of the flexible circuit board FCB. In plan view, the first circuit connection pads PD-O may be disposed closer to the upper portion of the flexible circuit board FCB than the signal pads PD. Each of the first circuit connection pads PD-O may be electrically connected to a corresponding signal pad PD among the signal pads PD through a line.

The first circuit connection pads PD-O may be electrically connected to the connection pads PD-C of the display panel DP. For example, the first circuit connection pads PD-O may be electrically connected to the connection pads PD-C by using an anisotropic conductive film or an ultrasonography method. The flexible circuit board FCB may be disposed on the display panel DP so that the first circuit connection pads PD-O respectively overlap the connection pads PD-C. The arrangement of the first circuit connection pads PD-O may correspond to the arrangement of the connection pads PD-C.

The second circuit connection pads PD-I may be arranged along the first direction DR1 in the third pad region PD-A3 adjacent to the other end of the flexible circuit board FCB. In plan view, the second circuit connection pads PD-I may be disposed closer to the lower portion of the flexible circuit board FCB than the signal pads PD. Each of the second circuit connection pads PD-I may be electrically connected to a corresponding signal pad PD among the signal pads PD through a line.

The second circuit connection pads PD-I may be connected to the main circuit board MCB (see FIG. 2). The second circuit connection pads PD-I may be respectively electrically connected to the driving pads of the main circuit board MCB (see FIG. 2) to receive an electrical signal provided by the main circuit board MCB (see FIG. 2).

The driving unit bonding region DIC-B may be disposed between the second pad region PD-A2 and the third pad region PD-A3 in plan view. For example, the second pad region PD-A2, the driving unit bonding region DIC-B, and the third pad region PD-A3 may be disposed along the second direction DR2. For example, the second pad region PD-A2 and the third pad region PD-A3 may be spaced apart from each other with the driving unit bonding region DIC-B interposed therebetween.

The flexible circuit board FCB may have flexibility. Accordingly, the flexible circuit board FCB may be disposed on the first pad region PD-A1 of the display panel DP and bent with respect to a bending axis extending in the first direction DR1. For example, the flexible circuit board FCB may be bent toward the rear surface of the display panel DP, and at least a portion of the flexible circuit board FCB may overlap the display panel DP in plan view.

The flexible circuit board FCB may include a heating unit HT and a heating signal pad PD-H. The heating signal pad PD-H may extend from the heating unit HT and be electrically connected to the heating unit HT. The heating signal pad PD-H may be electrically insulated from the first circuit connection pads PD-O, the second circuit connection pads PD-I, and the signal pads PD.

The heating unit HT may be disposed to overlap the driving unit bonding region DIC-B in the flexible circuit board FCB. For example, the heating unit HT may be disposed to overlap the signal pads PD. According to an embodiment, the heating unit HT may be disposed to extend to at least one of the second and third pad regions PD-A2 and PD-A3. Without being limited thereto, however, the heating unit HT may be spaced apart from the second and third pad regions PD-A2 and PD-A3.

Multiple heating signal pads PD-H may be provided and connected to both sides of the heating unit HT. The heating signal pads PD-H may be respectively disposed adjacent to both sides of the flexible circuit board FCB parallel to the second direction DR2. Without being limited thereto, the heating signal pads PD-H may be disposed side by side with the first circuit connection pads PD-O or the second circuit connection pads PD-I along the first direction DR1.

The heating unit HT may include a conductive pattern connected to the heating signal pad PD-H. The temperature of the heating unit HT may be increased by a current applied through the heating signal pad PD-H and the heating unit HT may transfer heat to the driving unit bonding region DIC-B. For example, in the process of bonding the driving unit DIC (see FIG. 2) on the driving unit bonding region DIC-B, the heating unit HT may locally transfer heat to the driving unit bonding region DIC-B of the flexible circuit board FCB to increase the temperature thereof. The above description may be applied to the heating unit HT disposed in the flexible circuit board FCB.

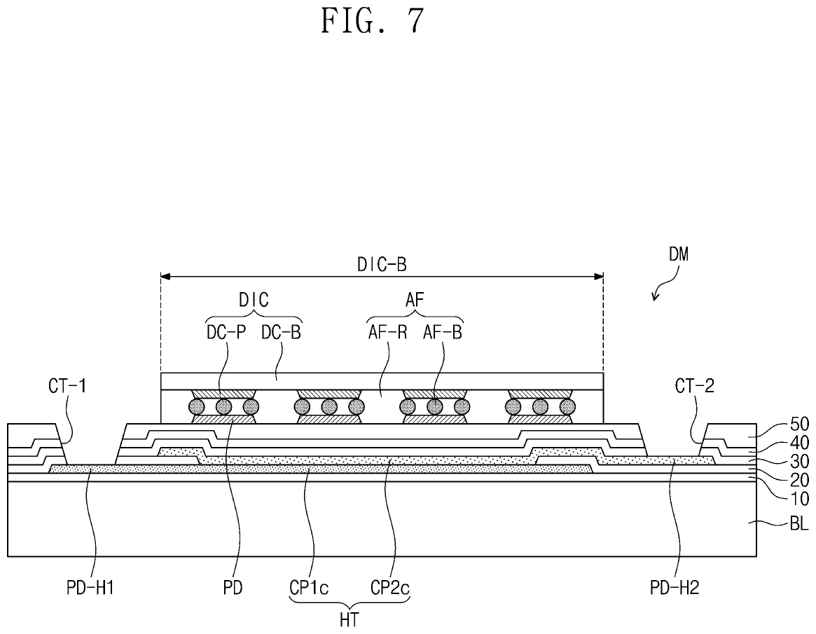

In an embodiment, a component having the driving unit bonding region DIC-B of the display module DM defined therein and providing a base surface on which the signal pads PD and the heating unit HT are disposed may be defined as a base unit (base). For example, as illustrated in FIG. 3A, a base layer BL (see FIG. 7) of the display panel DP having the driving unit bonding region DIC-B defined therein may correspond to the base unit of the display module DM. In another embodiment, as illustrated in FIG. 3B, a base substrate of the flexible circuit board FCB having the driving unit bonding region DIC-B defined therein and the base layer BL (see FIG. 7) of the display panel DP connected to the base substrate of the flexible circuit board FCB may correspond to the base unit of the display module DM.

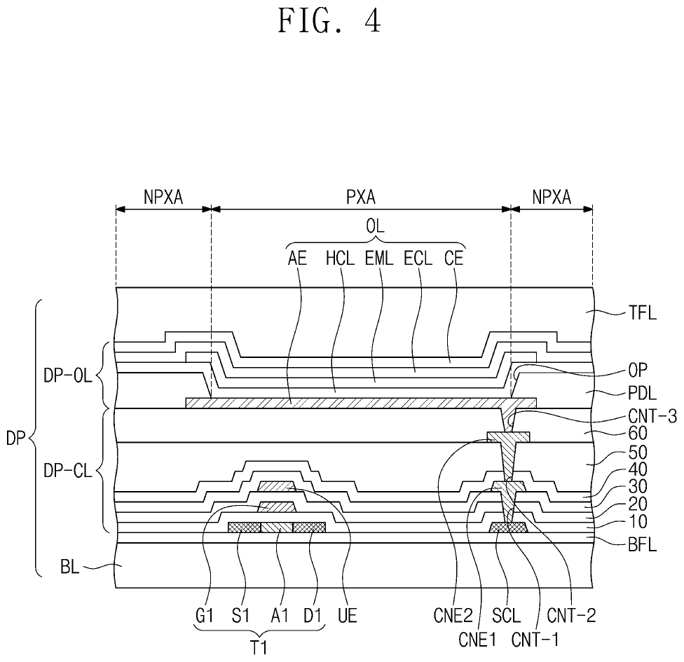

FIG. 4 is a schematic cross-sectional view of a display panel DP according to an embodiment. FIG. 4 illustrates a cross section of the display panel DP corresponding to the display region DA (see FIG. 3A).

Referring to FIG. 4, the display panel DP may include a base layer BL, a circuit layer DP-CL, a display element layer DP-OL, and an encapsulation layer TFL.

The base layer BL may provide a base surface on which the circuit layer DP-CL is disposed. The base layer BL may be a rigid substrate or a flexible substrate capable of being bent, folded, and/or rolled. For example, the base layer BL may include a glass substrate, a metal substrate, or a polymer substrate.

The base layer BL may have a multi-layered structure. For example, the base layer BL may include synthetic resin layers and at least one inorganic layer disposed between the synthetic resin layers. The synthetic resin layer of the base layer BL may contain at least one of an acrylic-based resin, a methacrylic-based resin, polyisoprene, a vinyl-based resin, an epoxy-based resin, a urethane-based resin, a cellulose-based resin, a siloxane-based resin, a polyamide-based resin, a perylene-based resin, and a polyimide-based resin. However, the material of the synthetic resin layer is not limited to the above examples.

At least one inorganic layer may be further disposed on the upper surface of the base layer BL. The inorganic layer may constitute a barrier layer and/or a buffer layer. FIG. 4 illustrates a buffer layer BFL disposed on the base layer BL. The buffer layer BFL may improve the bonding strength between the base layer BL and a semiconductor pattern of the circuit layer DP-CL. The buffer layer BFL may include at least one of aluminum oxide, titanium oxide, silicon oxide, silicon nitride, silicon oxynitride, zirconium oxide, and hafnium oxide.

The circuit layer DP-CL may be disposed on the base layer BL. The circuit layer DP-CL may include an insulating layer, a semiconductor pattern, and a conductive pattern. In the process of manufacturing the display panel DP, an insulating layer, a semiconductor layer, and a conductive layer may be formed through a method such as coating or deposition, and the insulating layer, the semiconductor layer, and the conductive layer may be patterned through photolithography processes. The insulating layer, the semiconductor pattern, and the conductive pattern included in the circuit layer DP-CL may form driving elements such as a transistor, signal lines, and pads.

The circuit layer DP-CL may include insulating layers 10 to 60, a transistor T1, a connection signal line SCL, and connection electrodes CNE1 and CNE2, which are disposed above the base layer BL. The insulating layers 10 to 60 may include first to sixth insulating layers 10 to 60 sequentially stacked on the base layer BL. However, embodiments of the insulating layers 10 to 60 included in the circuit layer DP-CL may be changed according to the configuration or manufacturing process of the circuit layer DP-CL.

The transistor T1 may include a semiconductor pattern and a gate electrode G1. The semiconductor pattern of the transistor T1 may be disposed on the buffer layer BFL and arranged in a predetermined or selected rule over the pixels. FIG. 4 illustrates a portion of the semiconductor pattern. The semiconductor pattern of the transistor T1 may include polysilicon, amorphous silicon, and/or metal oxide, but the disclosure is not limited to any one embodiment as long as the semiconductor pattern contains a semiconductor material.

The semiconductor pattern may include regions having different electrical properties depending on whether they are doped or reduced. For example, the semiconductor pattern may include a region having high conductivity as a result of being doped or reduction of a metal oxide, and the region having high conductivity may serve as an electrode or a signal line and this region may correspond to a source S1 and a drain D1 of the transistor T1. The semiconductor pattern may include a region having relatively low conductivity due to being undoped, and this region may correspond to a channel A1 (or active) of the transistor T1.

The connection signal line SCL may be formed from the semiconductor pattern. The connection signal line SCL may be disposed on the same layer as the source S1, the drain D1, and the channel A1 of the transistor T1. The connection signal line SCL may be connected to the semiconductor pattern of the transistor T1 in plan view.

The first insulating layer 10 may cover the semiconductor pattern of the transistor T1. Each of the first insulating layer 10 and the second to sixth insulating layers 20 to 60 to be described later may include at least one of an inorganic layer and an organic layer. For example, the inorganic layer may contain at least one of aluminum oxide, titanium oxide, silicon oxide, silicon oxynitride, zirconium oxide, and hafnium oxide. The organic layer may include at least one of an acrylic-based resin, a methacrylic-based resin, polyisoprene, a vinyl-based resin, an epoxy-based resin, a urethane-based resin, a cellulose-based resin, a siloxane-based resin, a polyamide-based resin, and a perylene-based resin. However, the material of the insulating layer is not limited to the above examples.

The gate electrode G1 may be disposed on the first insulating layer 10. The gate electrode G1 may overlap the channel A1 in plan view. The gate electrode G1 may function as a mask in a process of doping the semiconductor pattern.

The second insulating layer 20 may be disposed on the first insulating layer 10 to cover the gate electrode G1. An upper electrode UE may be disposed on the second insulating layer 20. The upper electrode UE may overlap the gate electrode G1 in plan view. The gate electrode G1 and the upper electrode UE that overlap each other may form a capacitor.

The third insulating layer 30 may be disposed on the second insulating layer 20 to cover the upper electrode UE. A first connection electrode CNE1 may be disposed on the third insulating layer 30. The first connection electrode CNE1 may be connected to the connection signal line SCL through a contact hole CNT-1 passing through the first to third insulating layers 10 to 30.

The fourth insulating layer 40 may be disposed on the third insulating layer 30. The fifth insulating layer 50 may be disposed on the fourth insulating layer 40. A second connection electrode CNE2 may be disposed on the fifth insulating layer 50. The second connection electrode CNE2 may be connected to the first connection electrode CNE1 through a contact hole CNT-2 passing through the fourth insulating layer 40 and the fifth insulating layer 50.

The sixth insulating layer 60 may be disposed on the fifth insulating layer 50 and cover the second connection electrode CNE2. In an embodiment, the fifth insulating layer 50 and the sixth insulating layer 60 may include an organic layer and provide a flat upper surface thereon. However, the disclosure is not limited thereto.

The display element layer DP-OL may be disposed on the circuit layer DP-CL. The display element layer DP-OL may include light-emitting elements OL and a pixel defining film PDL, and FIG. 4 illustrates a cross section corresponding to one light-emitting element OL. The light-emitting element OL may include an organic light-emitting element, an inorganic light-emitting element, a micro light-emitting diode (LED), a nano light-emitting diode (LED), or the like. The display element layer DP-OL may include a light-emitting region PXA corresponding to the light-emitting element OL and a non-light-emitting region NPXA surrounding the light-emitting region PXA.

In an embodiment, the light-emitting element OL may include a first electrode AE, a hole control layer HCL, a light-emitting layer EML, an electron control layer ECL, and a second electrode CE.

The first electrode AE may be disposed on the sixth insulating layer 60. The first electrode AE may be connected to the second connection electrode CNE2 through a contact hole CNT-3 passing through the sixth insulating layer 60.

The pixel defining film PDL may be disposed on the sixth insulating layer 60. A light-emitting opening OP exposing a portion of the first electrode AE may be defined in the pixel defining film PDL. The pixel defining film PDL may cover a portion of the upper surface of the first electrode AE. In an embodiment, the portion of the first electrode AE exposed by the light-emitting opening OP may correspond to the light-emitting region PXA.

The pixel defining film PDL may contain an organic material. The pixel defining film PDL according to an embodiment may have a predetermined or selected color. For example, the pixel defining film PDL may contain a base resin and a black pigment and/or a black dye mixed with the base resin. However, embodiments of the pixel defining film PDL are not limited thereto.

The hole control layer HCL may be disposed on the first electrode AE and the pixel defining film PDL. The hole control layer HCL may be a common layer commonly provided to the pixels. The hole control layer HCL may overlap the light-emitting region PXA and the non-light-emitting region NPXA. The hole control layer HCL may include at least one of a hole transport layer and a hole injection layer.

The light-emitting layer EML may be disposed on the hole control layer HCL. The light-emitting layer EML may be disposed in a region corresponding to the light-emitting opening OP of the pixel defining film PDL. The light-emitting layer EML may contain an organic light-emitting material, an inorganic light-emitting material, a quantum dot, a quantum rod, or the like. The light-emitting layer EML may be separately formed in each of the pixels. Each of the separately formed light-emitting layers EML may emit light of at least one color of red, green, or blue. Without being limited thereto, however, the light-emitting layer EML may be commonly provided to the pixels and emit blue light or white light.

The electron control layer ECL may be disposed on the light-emitting layer EML. The electron control layer ECL may be a common layer commonly provided to the pixels. The electron control layer ECL may overlap the light-emitting region PXA and the non-light-emitting region NPXA. The electron control layer ECL may include at least one of an electron transport layer and an electron injection layer.

The second electrode CE may be disposed on the electron control layer ECL. The second electrode CE may be a common layer commonly provided to the pixels. The second electrode CE may overlap the light-emitting region PXA and the non-light-emitting region NPXA. For example, multiple second electrodes CE of the light-emitting elements OL may have an integral shape and be disposed in the form of one common layer. A common voltage may be provided to the second electrode CE, and the second electrode CE may be referred to as a common electrode.

The encapsulation layer TFL may be disposed on and seal the display element layer DP-OL. The encapsulation layer TFL may include at least one thin film to improve the optical efficiency of the display element layer DP-OL or to protect the display element layer DP-OL. The encapsulation layer TFL may include at least one of an inorganic film and an organic film. The inorganic film of the encapsulation layer TFL may protect the light-emitting element OL from moisture/oxygen. The organic film of the encapsulation layer TFL may protect the light-emitting element OL from foreign substances such as dust particles. In an embodiment, the encapsulation layer TFL may include inorganic films and an organic film disposed between the inorganic films. However, embodiments of the encapsulation layer TFL are not limited thereto.

The inorganic film of the encapsulation layer TFL may contain at least one of aluminum oxide, titanium oxide, silicon oxide, silicon nitride, silicon oxynitride, zirconium oxide, and hafnium oxide. The organic film of the encapsulation layer TFL may contain an acrylic-based resin. However, the materials of the inorganic film and the organic film are not limited to the above examples.

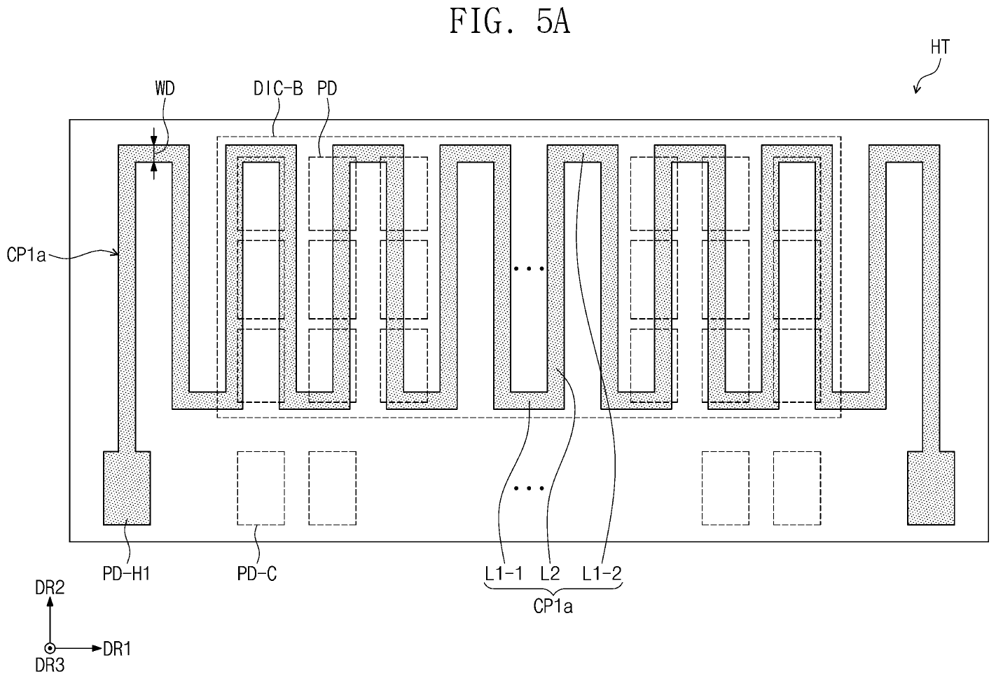

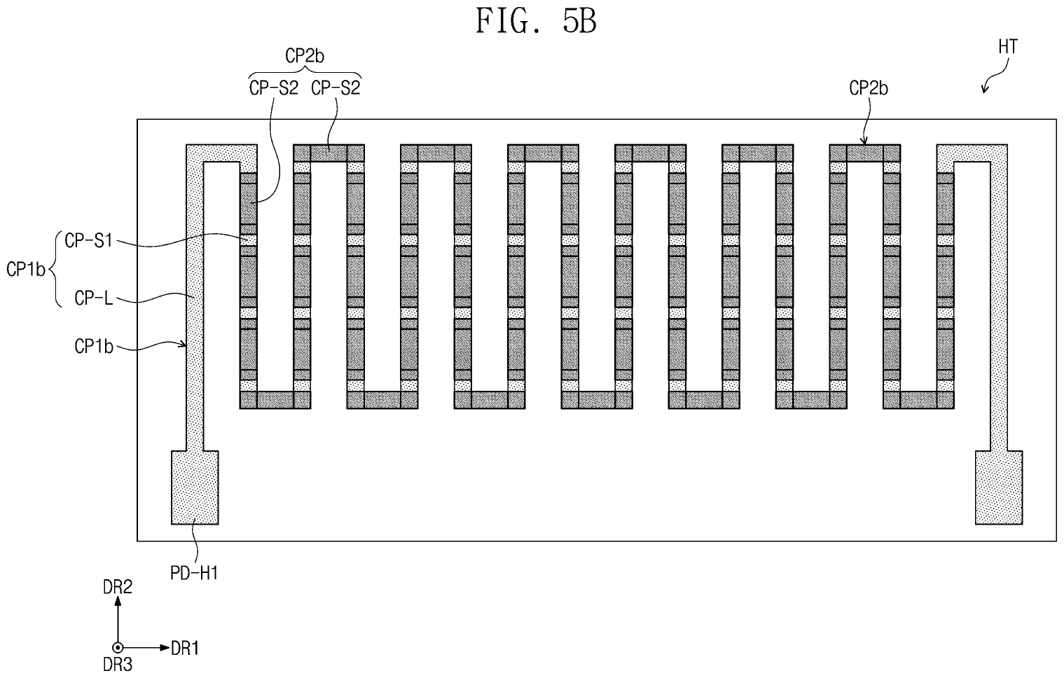

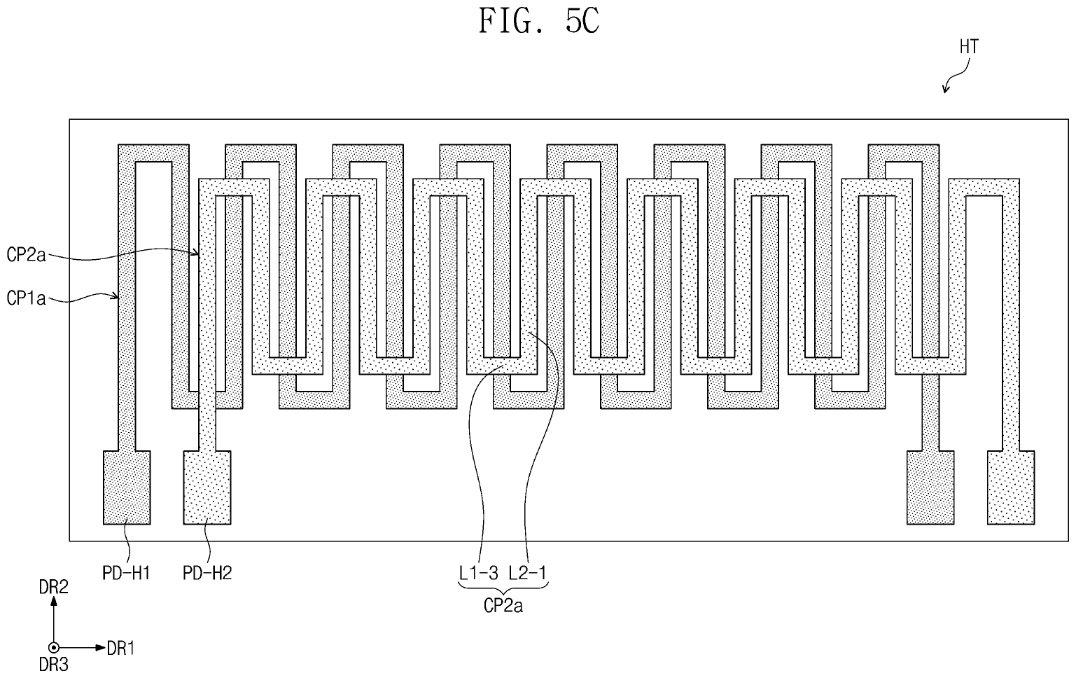

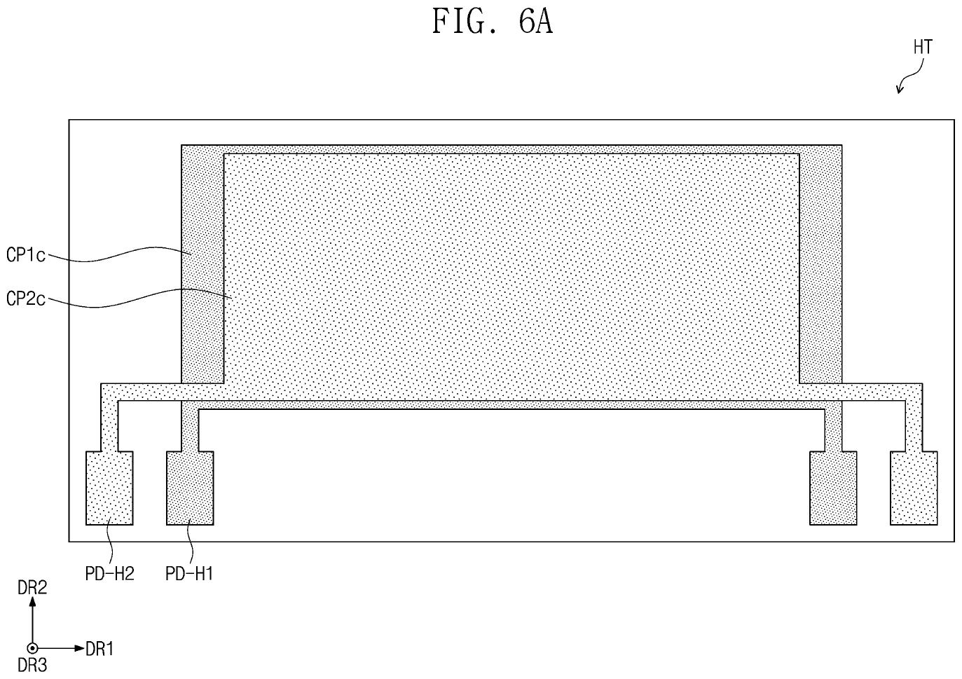

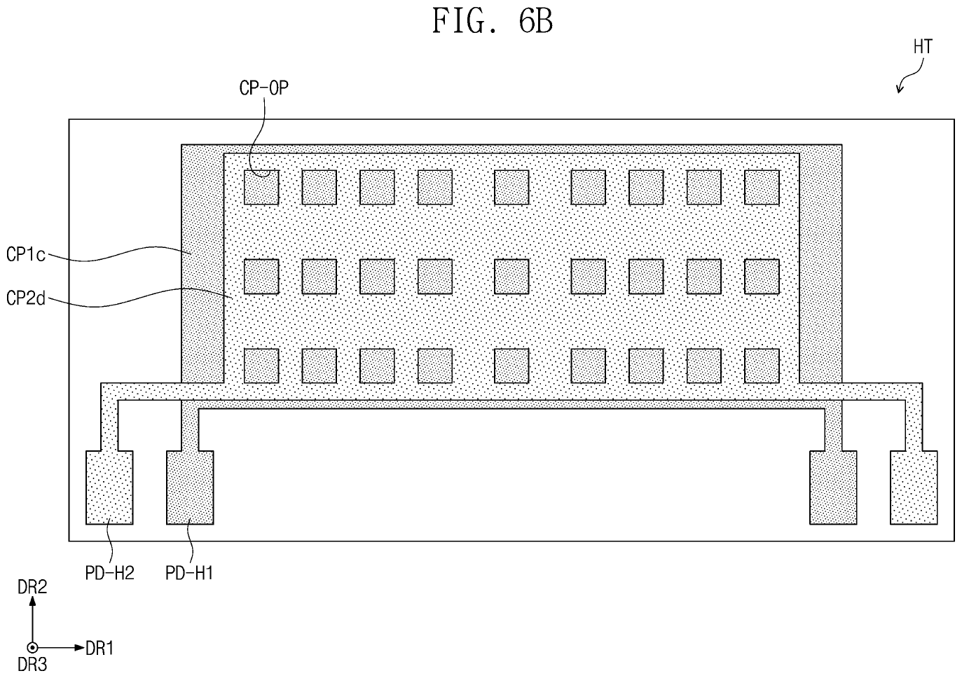

FIGS. 5A to 5C are schematic plan views of a heating unit HT according to an embodiment. FIGS. 6A and 6B are schematic plan views of a heating unit HT according to an embodiment. FIGS. 5A to 5C and FIGS. 6A and 6B illustrate various embodiments of the heating unit HT. The heating unit HT illustrated in FIGS. 5A to 5C and FIGS. 6A and 6B may be applied to the display panel DP (see FIG. 3A) or the flexible circuit board FCB (see FIG. 3B).

For convenience of understanding, in FIG. 5A, the connection pads PD-C, the driving unit bonding region DIC-B overlapping the heating unit HT, and the signal pads PD disposed in the driving unit bonding region DIC-B. PD are illustrated in a dotted line, and the illustrations of the connection pads PD-C, the driving bonding region DIC-B, and the signal pads PD are omitted in subsequent drawings. As illustrated in FIG. 5A, however, the heating unit HT of FIGS. 5B to 6B may also overlap the driving unit bonding region DIC-B and be disposed below the signal pads PD.

Referring to FIG. 5A, the heating unit HT may include a first conductive pattern CP1a disposed to overlap the driving unit bonding region DIC-B. The first conductive pattern CP1a may overlap the signal pads PD disposed in the driving unit bonding region DIC-B.

The first conductive pattern CP1a may have an integral line shape in plan view. For example, the first conductive pattern CP1a may include first line portions L1-1 and L1-2 extending in the first direction DR1 and second line portions L2 extending in the second direction DR2. The first line portions L1-1 and L1-2 and the second line portions L2 may be disposed on the same layer and connected to each other. The first line portions L1-1 and L1-2 and the second line portions L2 connected to each other may integrally form the first conductive pattern CP1a.

The second line portions L2 may be arranged along the first direction DR1, and the first line portions L1-1 and L1-2 may connect adjacent second line portions L2 to each other in the first direction DR1. Based on a second line portion L2, an end of the second line portion L2 may be connected to the first line portion L1-1 extending in the left direction, and another end thereof may be connected to the first line portion L1-2 extending in the right direction. For example, the first line portions L1-1 and L1-2 respectively connected to an end and another end of the second line portion L2 may extend in directions opposite to each other from a second line portion L2. Accordingly, the first conductive pattern CP1a may have a zigzag shape alternately extending along upper and lower directions parallel to the second direction DR2 in plan view. Without being limited thereto, however, the first conductive pattern CP1a may have a zigzag shape alternately extending along left and right directions parallel to the first direction DR1.

The first conductive pattern CP1a may be connected to a heating signal pad PD-H1. For example, the heating signal pad PD-H1 may be connected to the second line portion L2 of the first conductive pattern CP1a extending in the second direction DR2. Without being limited thereto, however, the heating signal pad PD-H1 may be connected to an end of the line of the first conductive pattern CP1a extending in the first direction DR1.

The heating signal pad PD-H1 may be formed on the same layer as the first conductive pattern CP1a and contain a same material as the first conductive pattern CP1a. For example, the heating signal pad PD-H1 and the first conductive pattern CP1a may be integrally formed. However, the disclosure is not limited thereto, and the heating signal pad PD-H1 may be disposed on the same layer as the connection pad PD-C and may be disposed on a layer different from that of the first conductive pattern CP1a. The heating signal pad PD-H1 and the first conductive pattern CP1a may be connected to each other through a contact hole.

Multiple heating signal pads PD-H1 may be provided and the heating signal pads PD-H1 may be arranged along the first direction DR1. The heating signal pads PD-H1 may be connected to a same first conductive pattern CP1a. The heating signal pads PD-H1 may be arranged side by side with the connection pads PD-C along the first direction DR1. The heating signal pads PD-H1 may be spaced apart from each other with the connection pads PD-C interposed therebetween and may be electrically connected to each other through the first conductive pattern CP1a. Without being limited thereto, however, the first conductive pattern CP1a may be disposed between the heating signal pads PD-H1 in the first direction DR1.

In case that a current is applied to the heating signal pad PD-H1, the heating unit HT may generate heat according to the resistance of the first conductive pattern CP1a. In the process of bonding the driving unit DIC (see FIG. 2) and the signal pads PD to each other, which are provided on the driving unit bonding region DIC-B, the heating unit HT may locally provide heat to the driving unit bonding region DIC-B of the display panel DP (see FIG. 3A), for which heat is needed.

The resistance value of the first conductive pattern CP1a may be designed by controlling the material, overall length, and width WD of the first conductive pattern CP1a. The heating temperature to be implemented through the heating unit HT may vary according to the resistance value of the first conductive pattern CP1a. The shape of the first conductive pattern CP1a illustrated in FIG. 5A is only an example, and the shape of the first conductive pattern CP1a is not limited to any one embodiment as long as it provides the driving unit bonding region DIC-B with heat having a temperature sufficient to bond the signal pads PD and the driving unit DIC (see FIG. 2) to each other.

The first conductive pattern CP1a of FIG. 5A may be disposed on the same layer as at least one of the conductive elements disposed in the circuit layer DP-CL (see FIG. 4). The first conductive pattern CP1a may include the same material as at least one of the conductive elements of the circuit layer DP-CL (see FIG. 4) and be simultaneously formed in a same process step. For example, the first conductive pattern CP1a may be disposed on the same layer as at least one of the gate electrode G1 (see FIG. 4), the upper electrode UE (see FIG. 4), and the connection electrodes CNE1 and CNE2 (see FIG. 4) of the circuit layer DP-CL (see FIG. 4) and formed therewith in a same process step. Therefore, the heating unit HT may be formed without adding a separate process step or a separate mask.

Referring to FIG. 5B, the heating unit HT may include a first conductive pattern CP1b and a second conductive pattern CP2b. The first conductive pattern CP1b and the second conductive pattern CP2b may be disposed on different layers. For example, the second conductive pattern CP2b may be disposed above the first conductive pattern CP1b. The second conductive pattern CP2b may be disposed directly on and come in contact with the first conductive pattern CP1b. Without being limited thereto, however, at least one insulating layer may be disposed between the first conductive pattern CP1b and the second conductive pattern CP2b in the thickness direction (e.g., the third direction DR3), and the second conductive pattern CP2b and the first conductive pattern CP1b may come in contact with each other through a through-hole defined in the insulating layer.

The first conductive pattern CP1b may include a first pattern CP-L connected to the heating signal pad PD-H1 and second patterns CP-S1 spaced apart from the first pattern CP-L in plan view. The first pattern CP-L and the second patterns CP-S1 may be disposed on a same layer and contain a same material. However, the disclosure is not limited thereto, and the first pattern CP-L and the second patterns CP-S1 may contain different materials from each other.

The heating signal pad PD-H1 and the first pattern CP-L may be integrally formed on a same layer. The first pattern CP-L may extend in a direction from the heating signal pad PD-H1. For example, the first pattern CP-L may extend in the second direction DR2 from one end of the heating signal pad PD-H1. However, the shape of the first pattern CP-L is not limited to any one embodiment as long as it is connected to the heating signal pad PD-H1.

Multiple heating signal pads PD-H1 may be provided, and multiple first patterns CP-L may also be provided to correspond to the heating signal pads PD-H1. The first patterns CP-L may be respectively connected to the heating signal pads PD-H1.

The second patterns CP-S1 may be disposed to be spaced apart from each other. The second patterns CP-S1 may correspond to those formed by cutting portions of the first conductive pattern CP1a of FIG. 5A. However, this is illustrated as an example, and the arrangement of the second patterns CP-S1 is not limited to any one embodiment.

The second conductive pattern CP2b may include third patterns CP-S2 spaced apart from each other in plan view. The third patterns CP-S2 may respectively connect adjacent second patterns CP-S1 to each other. For example, a third pattern CP-S2 extending in the first direction DR1 among the third patterns CP-S2 may come in contact with one end of each of the adjacent second patterns CP-S1 in the first direction DR1 to connect the second patterns CP-S1 to each other. A third pattern CP-S2 extending in the second direction DR2 among the third patterns CP-S2 may come in contact with one end of each of the second patterns CP-S1 facing each other in the second direction DR2 to connect the second patterns CP-S1 to each other.

The third patterns CP-S2 may be disposed directly on the second patterns CP-S1 and come in contact with corresponding second patterns CP-S1 among the second patterns CP-S1. Without being limited thereto, however, at least one insulating layer may be disposed on the second patterns CP-S1, and the third patterns CP-S2 may be respectively connected to the second patterns CP-S1 through a through-hole formed through the insulating layer.

The second patterns CP-S1 may be connected to each other by the third patterns CP-S2 to have a single line shape. For example, the second patterns CP-S1 and the third patterns CP-S2, which are connected to each other, may have a line shape similar to that of the first conductive pattern CP1a of FIG. 5A. The second patterns CP-S1 and the third patterns CP-S2, which are connected to each other, may have a zigzag shape alternately extending along upper and lower directions parallel to the second direction DR2. Without being limited thereto, however, the second patterns CP-S1 and the third patterns CP-S2, which are connected to each other, may have a zigzag shape alternately extending along left and right directions parallel to the first direction DR1.

The second patterns CP-S1 and the third patterns CP-S2 may contain different materials. As the second patterns CP-S1 and the third patterns CP-S2 including different materials come in contact with each other, contact resistance may occur at the contact portion therebetween. The resistance of the heating unit HT may be increased by the contact resistance, and in the bonding process of the driving unit DIC (see FIG. 2), the heating unit HT may generate enough heat to bond the driving unit DIC (see FIG. 2) in the driving unit bonding region DIC-B (see FIG. 5A) and transfer heat effectively.

Referring to FIG. 5C, the heating unit HT may include a first conductive pattern CP1a and a second conductive pattern CP2a. The first conductive pattern CP1a and the second conductive pattern CP2a may be disposed on different layers. For example, the second conductive pattern CP2a may be disposed above the first conductive pattern CP1a. At least one insulating layer may be disposed between the first conductive pattern CP1a and the second conductive pattern CP2a in the third direction DR3, and the first conductive pattern CP1a and the second conductive pattern CP2a may be electrically insulated from each other.

The description of the first conductive pattern CP1a described above with reference to FIG. 5A may be equally applied to the first conductive pattern CP1a illustrated in FIG. 5C.

The second conductive pattern CP2a may have an integral line shape in plan view. For example, the second conductive pattern CP2a may include third line portions L1-3 extending in the first direction DR1 and fourth line portions L2-1 extending in the second direction DR2. The third line portions L1-3 and the fourth line portions L2-1 may be connected to each other to integrally form the second conductive pattern CP2a.

The second conductive pattern CP2a may have a zigzag shape alternately extending along upper and lower directions parallel to the second direction DR2. In plan view, the second conductive pattern CP2a may be disposed to be displaced from the first conductive pattern CP1a in the first direction DR1. For example, the fourth line portion L2-1 of the second conductive pattern CP2a may be disposed between the second line portions L2 (see FIG. 5A) of the first conductive pattern CP1a in plan view. However, the disclosure is not limited thereto, and the fourth line portions L2-1 of the second conductive pattern CP2a may respectively overlap the second line portions L2 (see FIG. 5A) of the first conductive pattern CP1a.

The shape of the second conductive pattern CP2a illustrated in FIG. 5C is only an example, and without being limited thereto, the second conductive pattern CP2a may have a zigzag shape alternately extending along left and right directions parallel to the first direction DR1. The second conductive pattern CP2a may be disposed across the first conductive pattern CP1a in plan view. The shapes of the first conductive pattern CP1a and the second conductive pattern CP2a may be variously changed.

The total length of the first conductive pattern CP1a and the total length of the second conductive pattern CP2a may be different from each other. A material included in the first conductive pattern CP1a and a material included in the second conductive pattern CP2a may be different from each other. However, the disclosure is not limited thereto, and the first conductive pattern CP1a and the second conductive pattern CP2a may have a same length, shape, and/or material.

FIG. 5C illustrates that the heating unit HT includes the first conductive pattern CP1a of FIG. 5A and the second conductive pattern CP2a disposed on the first conductive pattern CP1a, but without being limited thereto, the first conductive pattern disposed below the second conductive pattern CP2a may correspond to the first conductive pattern CP1b and the second conductive pattern CP2b of FIG. 5B. For example, the heating unit HT may include the first and second conductive patterns CP1b and CP2b of FIG. 5B and may further include a third conductive pattern identical to the second conductive pattern CP2a of FIG. 5C and disposed on the second conductive pattern CP2b.

The second conductive pattern CP2a may be connected to the heating signal pad PD-H2. Hereinafter, the heating signal pad PD-H1 connected to the first conductive pattern CP1a is referred to as a first heating signal pad PD-H1, and the heating signal pad PD-H2 connected to the second conductive pattern CP2a is referred to as a second heating signal pad PD-H2.

The second heating signal pad PD-H2 may be connected to the fourth line portion L2-1 of the second conductive pattern CP2a extending in the second direction DR2. Without being limited thereto, however, the second heating signal pad PD-H2 may be connected to an end of the line of the second conductive pattern CP2a extending in the first direction DR1.

The second heating signal pad PD-H2 may be spaced apart from the first heating signal pad PD-H1 in plan view. For example, the second heating signal pad PD-H2 and the first heating signal pad PD-H1 may be arranged along the first direction DR1.

Multiple second heating signal pads PD-H2 may be provided and the second heating signal pads PD-H2 may be arranged along the first direction DR1. The second heating signal pads PD-H2 may be connected to the same second conductive pattern CP2a. The second heating signal pads PD-H2 and the first heating signal pads PD-H1 may be alternately disposed along the first direction DR1. Without being limited thereto, however, the second heating signal pads PD-H2 may be arranged along the first direction DR1 in a region between the first heating signal pads PD-H1. As long as the first and second heating signal pads PD-H1 and PD-H2 are respectively connected to the first and second conductive patterns CP1a and CP2a, the arrangement shape thereof is not limited to any one embodiment.

As the first heating signal pad PD-H1 is disposed on the same layer as the first conductive pattern CP1a and the second heating signal pad PD-H2 is disposed on the same layer as the second conductive pattern CP2a, the first heating signal pad PD-H1 and the second heating signal pad PD-H2 may be disposed on different layers. However, the disclosure is not limited thereto, and the first heating signal pad PD-H1 and the second heating signal pad PD-H2 may be disposed on a same layer, but may be respectively disposed on layers different from those of the first and second conductive patterns CP1a and CP2a. The first heating signal pad PD-H1 and the second heating signal pad PD-H2 may be respectively connected to the first conductive pattern CP1a and the second conductive pattern CP2a through contact holes.

The first heating signal pad PD-H1 may contain the same material as the first conductive pattern CP1a, and the second heating signal pad PD-H2 may contain the same material as the second conductive pattern CP2a. The first heating signal pad PD-H1 and the second heating signal pad PD-H2 may contain different materials from each other. Without being limited thereto, however, the first heating signal pad PD-H1 and the second heating signal pad PD-H2 may contain a same material.

In case that a current is applied to the first heating signal pad PD-H1, the first conductive pattern CP1a may generate heat according to the resistance of the first conductive pattern CP1a. Likewise, in case that a current is applied to the second heating signal pad PD-H2, the second conductive pattern CP2a may generate heat according to the resistance of the second conductive pattern CP2a. The current value applied to the first heating signal pad PD-H1 and the current value applied to the second heating signal pad PD-H2 may be controlled differently according to the heating temperature to be implemented through the heating unit HT.

The resistance value of the second conductive pattern CP2a may be designed by controlling the material, overall length, and width of the second conductive pattern CP2a. The resistance value of the first conductive pattern CP1a and the resistance value of the second conductive pattern CP2a may be designed in various ways according to the heating temperature to be implemented through the heating unit HT. By controlling the heating of the first conductive pattern CP1a and the heating of the second conductive pattern CP2a independently of each other, the temperature in the driving unit bonding region DIC-B (see FIG. 5A) may be precisely controlled in the bonding process of the driving unit DIC (see FIG. 2).

Each of the first conductive pattern CP1a and the second conductive pattern CP2a of FIG. 5C may be disposed on the same layer as at least one of the conductive elements (e.g., the gate electrode G1, the upper electrode UE, and the connection electrodes CNE1 and CNE2 (see FIG. 4)) disposed in the circuit layer DP-CL (see FIG. 4). For example, the first conductive pattern CP1a may be disposed on the same layer as the gate electrode G1 (see FIG. 4), and the second conductive pattern CP2a may be disposed on the same layer as the upper electrode UE (see FIG. 4). However, the disclosure is not necessarily limited thereto. The first conductive pattern CP1a and the second conductive pattern CP2a may be formed in the same process step as at least one of the conductive elements of the circuit layer DP-CL (see FIG. 4). Therefore, the heating unit HT may be formed without adding a separate process step or a separate mask.

Referring to FIG. 6A, the heating unit HT may include a first conductive pattern CP1c and a second conductive pattern CP2c. The first conductive pattern CP1c and the second conductive pattern CP2c may be disposed on different layers. For example, the second conductive pattern CP2c may be disposed above the first conductive pattern CP1c, and at least one insulating layer may be disposed between the second conductive pattern CP2c and the first conductive pattern CP1c in the third direction DR3.

The first conductive pattern CP1c may include a planar portion parallel to the first and second directions DR1 and DR2 and having a predetermined or selected planar area. The second conductive pattern CP2c may also include a planar portion parallel to the first and second directions DR1 and DR2 and having a predetermined or selected planar area.

The first conductive pattern CP1c and the second conductive pattern CP2c may be electrically connected to each other. The planar portion of the first conductive pattern CP1c and the planar portion of the second conductive pattern CP2c may overlap each other in plan view and come in contact with each other in the overlapping region. For example, a portion of the first conductive pattern CP1c and a portion of the second conductive pattern CP2c may come in contact with each other.

The first conductive pattern CP1c and the second conductive pattern CP2c may contain different materials from each other. Accordingly, contact resistance may occur in a region in which the first conductive pattern CP1c and the second conductive pattern CP2c come in contact with each other. The resistance of the heating unit HT may be increased by the contact resistance, and the heating unit HT may generate enough heat to bond the driving unit DIC (see FIG. 2) in the driving unit bonding region DIC-B (see FIG. 5A) and transfer heat effectively.

The area of each of the first and second conductive patterns CP1c and CP2c and the area of a portion in which the first and second conductive patterns CP1c and CP2c come in contact with each other may be designed in various ways according to the heating temperature to be implemented through the heating unit HT.

The first conductive pattern CP1c may be connected to the first heating signal pad PD-H1. The first conductive pattern CP1c may be integrally formed on the same layer as the first heating signal pad PD-H1. The first conductive pattern CP1c may include a line portion protruding toward a direction from the planar portion, and an end of the line portion may be connected to the first heating signal pad PD-H1. However, the disclosure is not limited thereto, and the first conductive pattern CP1c and the first heating signal pad PD-H1 may be disposed on different layers and connected to each other through a contact hole.

The second conductive pattern CP2c may be connected to the second heating signal pad PD-H2. The second conductive pattern CP2c may be integrally formed on the same layer as the second heating signal pad PD-H2. The second conductive pattern CP2c may include a line portion protruding toward a direction from the planar portion, and an end of the line portion may be connected to the second heating signal pad PD-H2. However, the disclosure is not limited thereto, and the second conductive pattern CP2c and the second heating signal pad PD-H2 may be disposed on different layers and connected to each other through a contact hole.

Multiple of each of the first heating signal pad PD-H1 and the second heating signal pad PD-H2 may be provided and multiple ones thereof may be arranged along the first direction DR1. For example, the first heating signal pads PD-H1 may be arranged along the first direction DR1 in a region between the second heating signal pads PD-H2. However, the arrangement shape thereof is not limited to any one embodiment as long as the first and second heating signal pads PD-H1 and PD-H2 are respectively connected to the first and second conductive patterns CP1c and CP2c.

By applying a current to the first heating signal pad PD-H1, the first conductive pattern CP1c may be heated, and by applying a current to the second heating signal pad PD-H2, the second conductive pattern CP2c may be heated. The current value applied to the first heating signal pad PD-H1 and the current value applied to the second heating signal pad PD-H2 may be controlled differently according to the heating temperature to be implemented through the heating unit HT.

Referring to FIG. 6B, according to an embodiment, a pattern opening CP-OP may be defined in the second conductive pattern CP2d. The second conductive pattern CP2d of FIG. 6B may correspond to the second conductive pattern CP2c of FIG. 6A in which the pattern opening CP-OP is formed.

The pattern opening CP-OP may be formed to pass through the second conductive pattern CP2d in a region in which the first conductive pattern CP1c and the second conductive pattern CP2d come in contact with each other. A portion of the upper surface of the first conductive pattern CP1c may be exposed from the second conductive pattern CP2d through the pattern opening CP-OP.

Multiple pattern openings CP-OP may be provided and the pattern openings CP-OP may be arranged along a direction in the second conductive pattern CP2d. For example, the pattern openings CP-OP may be arranged along the first and second directions DR1 and DR2, and the second conductive pattern CP2d may have a mesh shape in plan view. However, the shape and arrangement of the pattern openings CP-OP illustrated in FIG. 6B are only examples and may be variously changed according to a region in which contact between the first conductive pattern CP1c and the second conductive pattern CP2d is required.

A region in which the first conductive pattern CP1c and the second conductive pattern CP2d come in contact with each other may be locally formed by the pattern openings CP-OP. For example, by adjusting the area and formation position of the pattern openings CP-OP, the region and area of the portion in which the first conductive pattern CP1c and the second conductive pattern CP2d come in contact with each other may be changed. In the portion in which the first conductive pattern CP1c and the second conductive pattern CP2d come in contact with each other, heat may be effectively generated due to contact resistance. Accordingly, in the process of bonding the driving unit DIC (see FIG. 2), heat may be transferred to a region in which heat is intensively needed in the driving unit bonding region DIC-B (see FIG. 5A).

However, embodiments of the heating unit HT for local heating are not limited thereto, and by controlling the formation region and shape of the through-holes of the insulating layer disposed between the first conductive pattern CP1c and the second conductive pattern CP2d, the region and area in which the first conductive pattern CP1c and the second conductive pattern CP2d come in contact with each other may be controlled.

Each of the first conductive pattern CP1c and the second conductive patterns CP2c and CP2d of FIGS. 6A and 6B may be disposed on the same layer as at least one of the conductive elements (e.g., the gate electrode G1, the upper electrode UE, and the connection electrodes CNE1 and CNE2 (see FIG. 4)) disposed in the circuit layer DP-CL (see FIG. 4). The first conductive pattern CP1c and the second conductive patterns CP2c and CP2d may be formed in the same process step as at least one of the conductive elements of the circuit layer DP-CL (see FIG. 4). Accordingly, the heating unit HT may be formed without adding a separate process step or a separate mask.

FIG. 7 is a schematic cross-sectional view of a display module DM according to an embodiment. FIG. 7 illustrates a cross section of the display module DM corresponding to the driving unit bonding region DIC-B, and a cross section of the heating unit HT according to an embodiment illustrated in FIG. 6A as well.

Referring to FIG. 7, the heating unit HT may be disposed between the base layer BL and the signal pads PD. The heating unit HT may include a first conductive pattern CP1c and a second conductive pattern CP2c, and the aforementioned description may be applied to each component.

The first conductive pattern CP1c of the heating unit HT may be disposed on the base layer BL. For example, the first conductive pattern CP1c may be disposed on the first insulating layer 10. The first conductive pattern CP1c may be disposed on the same layer as the gate electrode G1 (see FIG. 4) and may be simultaneously formed therewith in a same process step. However, the disclosure is not limited thereto, and the configuration of the insulating layer disposed below the first conductive pattern CP1c may vary.

The first conductive pattern CP1c may be integrally formed on the same layer as the first heating signal pad PD-H1. For example, the first heating signal pad PD-H1 may be formed to extend from the first conductive pattern CP1c in plan view. However, the disclosure is not necessarily limited thereto, and the first heating signal pad PD-H1 may be disposed on the same layer as the signal pads PD and connected to the first conductive pattern CP1c through a contact-hole.

The second insulating layer 20 may be disposed on the first conductive pattern CP1c. In the second insulating layer 20, a through-hole exposing a portion of the upper surface of the first conductive pattern CP1c may be defined in a region corresponding to the driving unit bonding region DIC-B. For example, the portion of the upper surface of the first conductive pattern CP1c may be exposed from the second insulating layer 20 in the driving unit bonding region DIC-B.

The second conductive pattern CP2c may be disposed on the first conductive pattern CP1c. A portion of the second conductive pattern CP2c may be disposed on the second insulating layer 20. The second conductive pattern CP2c may come in contact with the first conductive pattern CP1c in the driving unit bonding region DIC-B.

The first conductive pattern CP1c and the second conductive pattern CP2c may contain different conductive materials from each other. Contact resistance may occur as the first conductive pattern CP1c and the second conductive pattern CP2c, which contain different materials, come in contact with each other. Accordingly, heat may be effectively generated in a region in which the first conductive pattern CP1c and the second conductive pattern CP2c come in contact with each other, and in the process of bonding the driving unit DIC, the heating unit HT may transfer heat required for bonding the driving unit DIC in the driving unit bonding region DIC-B.

The second conductive pattern CP2c may be disposed on the same layer as the upper electrode UE (see FIG. 4) and simultaneously formed therewith in a same process step. However, the stacking position of the second conductive pattern CP2c is not limited to any one embodiment as long as the second conductive pattern CP2c is disposed above the first conductive pattern CP1c. For example, the second conductive pattern CP2c may be formed simultaneously with at least one of the connection electrodes CNE1 and CNE2 (see FIG. 4). Accordingly, the configuration of the insulating layer disposed between the first conductive pattern CP1c and the second conductive pattern CP2c may also vary.

The second conductive pattern CP2c may be integrally formed on the same layer as the second heating signal pad PD-H2. For example, the second heating signal pad PD-H2 may be formed to extend from the second conductive pattern CP2c in plan view. However, the disclosure is not necessarily limited thereto, and the second heating signal pad PD-H2 may be disposed on the same layer as the signal pads PD and connected to the second conductive pattern CP2c through a contact-hole.

At least a portion of the first heating signal pad PD-H1 may be exposed to the outside through a first through-hole CT-1 passing through the second to fifth insulating layers 20 to 50 disposed above the first heating signal pad PD-H1. At least a portion of the second heating signal pad PD-H2 may be exposed to the outside through a second through-hole CT-2 passing through the third to fifth insulating layers 30 to 50 disposed above the second heating signal pad PD-H2.

In the process of bonding the driving unit DIC, the first conductive pattern CP1c may be heated by applying a current to the first heating signal pad PD-H1 exposed through the first through-hole CT-1. The second conductive pattern CP2c may be heated by applying a current to the second heating signal pad PD-H2 exposed through the second through hole CT-2.

The signal pads PD may be disposed on and overlap the heating unit HT. At least one insulating layer may be disposed between the second conductive pattern CP2c of the heating unit HT and the signal pads PD. For example, the third to fifth insulating layers 30 to 50 may be disposed between the second conductive pattern CP2c and the signal pads PD. Accordingly, the heating unit HT and the signal pads PD may be electrically insulated from each other. However, the configuration of the insulating layers disposed between the second conductive pattern CP2c and the signal pads PD is not limited thereto and may vary.

The driving unit DIC may be disposed on the driving unit bonding region DIC-B. The driving unit DIC may be disposed on the signal pads PD and electrically connected to the signal pads PD through a conductive adhesive member AF. The driving unit DIC may include a base substrate DC-B and driving signal pads DC-P disposed on the base substrate DC-B. The driving signal pads DC-P may be respectively disposed to correspond to the signal pads PD. For example, the driving signal pads DC-P may respectively face and overlap the signal pads PD.

The conductive adhesive member AF may be disposed between the signal pads PD and the driving unit DIC. The conductive adhesive member AF may electrically connect the signal pads PD and the driving signal pads DC-P of the driving unit DIC to each other.

The conductive adhesive member AF may include a base resin portion AF-R and conductive particles AF-B disposed inside the base resin portion AF-R. In an embodiment, the conductive adhesive member AF may be an anisotropic conductive film.

The base resin portion AF-R may fill a space between the signal pads PD and the driving unit DIC. The base resin portion AF-R may include a polymer material. For example, the base resin portion AF-R may include at least one of an acrylic-based polymer, a silicone-based polymer, a urethane-based polymer, and an imide-based polymer. The base resin portion AF-R may be formed by heat-curing or photo-curing a base resin such as an acrylic-based resin, a silicone-based resin, a urethane-based resin, and/or an imide-based resin.

The conductive particles AF-B may be metal particles or alloy particles in which multiple metals are mixed. For example, the conductive particles AF-B may be metal or metal alloy particles including at least one of silver, copper, bismuth, zinc, indium, tin, nickel, cobalt, chromium, and iron. In another embodiment, the conductive particles AF-B may include a core portion formed of a polymer resin or the like and a coating layer covering the core portion and having conductivity.

The conductive particles AF-B may be aligned between the signal pads PD and driving signal pads DC-P corresponding to each other in the base resin portion AF-R. The conductive particles AF-B may have anisotropy so that a current flows in the pressing direction through pressing in the process of bonding the driving unit DIC. Accordingly, the signal pads PD may be respectively electrically connected to the driving signal pads DC-P through the conductive particles AF-B.

In the process of bonding the driving unit DIC on the driving unit bonding region DIC-B by the conductive adhesive member AF, the base resin portion AF-R may need to be softened or hardened. In order to soften or harden the base resin portion AF-R, it may be necessary to provide heat to the driving unit bonding region DIC-B. The heating unit HT according to the disclosure may provide heat to the driving unit bonding region DIC-B in the process of bonding the driving unit DIC.

As the display module DM includes the heating unit HT, a region that needs heat supply in the display module DM may be locally heated. The heating temperature of the heating unit HT may be uniformly and precisely controlled according to the design of the current applied to the heating signal pads PD-H1 and PD-H2 or the resistance value of the conductive patterns CP1c and CP2c. As the display module DM includes the heating unit HT, providing a high-temperature external bonding device on the driving unit DIC to bond the driving unit DIC may be omitted or the temperature of the external bonding device may be lowered. Accordingly, it is possible to prevent the other components of the display module DM from being damaged by the high-temperature external bonding device.

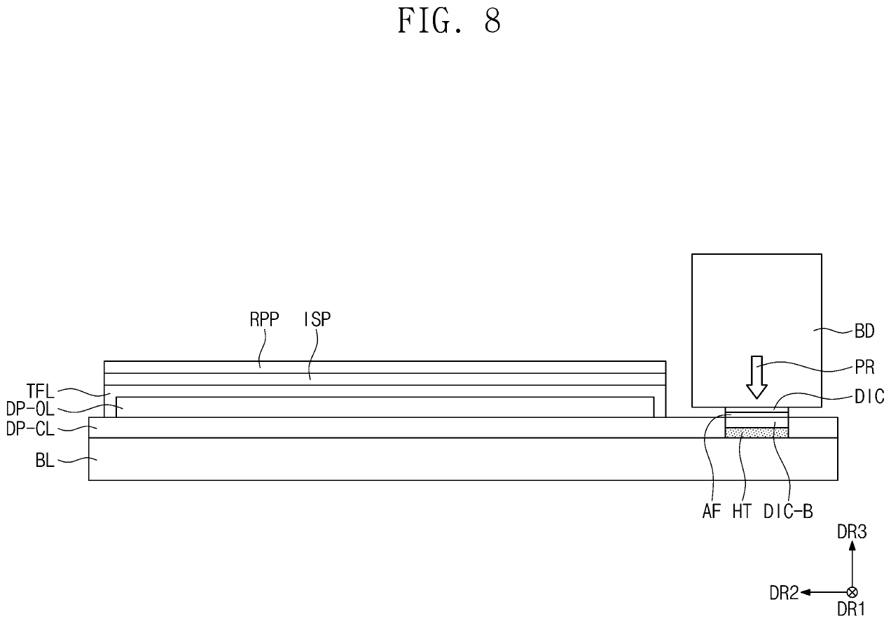

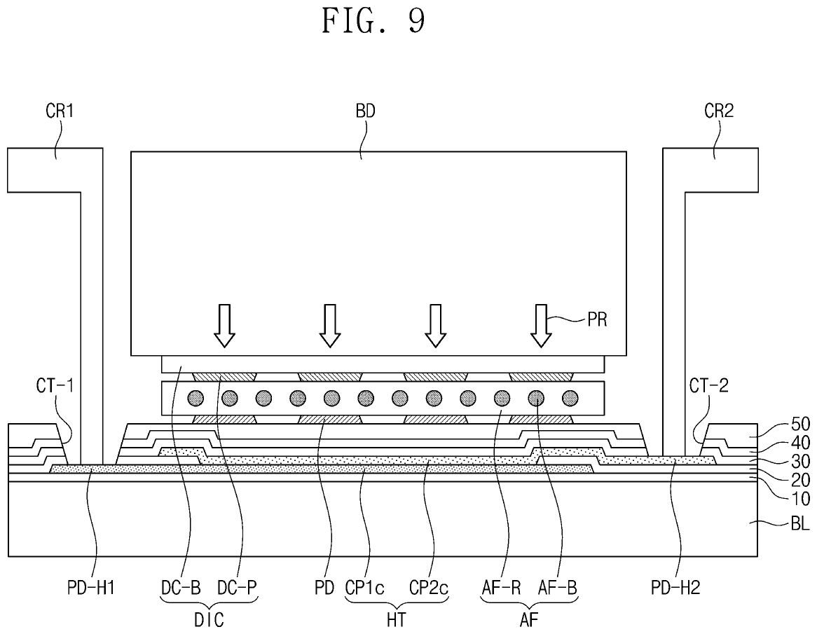

FIGS. 8 and 9 are schematic cross-sectional views illustrating a step of a method of manufacturing a display module according to an embodiment. FIGS. 8 and 9 briefly illustrate a step of bonding the driving unit DIC to the driving unit bonding region DIC-B.

A method of manufacturing a display module according to an embodiment may include providing a display module, in which signal pads are disposed, in a driving unit (driver) bonding region, providing a conductive adhesive member and a driving unit (driver) on the driving unit bonding region of the display module, and electrically connecting the driving unit and the signal pads to each other. In an embodiment, the electrical connection of the driving unit to the signal pads may correspond to a process of bonding the driving unit.

Referring to FIGS. 8 and 9, in order to electrically connect the driving unit DIC to the signal pads PD, the conductive adhesive member AF and the driving unit DIC may be provided on the driving unit bonding region DIC-B. The conductive adhesive member AF may be disposed between the driving unit DIC and the signal pads PD.

An external bonding device BD may be provided on the driving unit DIC to electrically connect the driving unit DIC to the signal pads PD. According to an embodiment, the external bonding device BD may provide the driving unit DIC on the driving unit bonding region DIC-B by vacuum-adsorbing the driving unit DIC. Without being limited thereto, however, the driving unit DIC may be provided on the driving unit bonding region DIC-B by a separate device other than the external bonding device BD.

The electrical connection of the driving unit DIC to the signal pads PD may include heating and pressing the conductive adhesive member AF. The external bonding device BD may apply pressure PR to the conductive adhesive member AF on the driving unit DIC and, if necessary, apply heat and pressure PR to the conductive adhesive member AF.

A high-temperature environment may be required to adhere the conductive adhesive member AF to the driving unit DIC and the signal pads PD. For example, a temperature of about 150 degrees (° C.) to about 200 degrees (° C.) may be required to adhere the conductive adhesive member AF to the driving unit DIC and the signal pads PD.

In the method of manufacturing the display module according to an embodiment, the conductive adhesive member AF may be heated by heating the heating unit HT included in the display module DM (see FIG. 7). In order to heat the heating unit HT, current applying devices CR1 and CR2 may be respectively provided to the first heating signal pad PD-H1 and the second heating signal pad PD-H2 connected to the heating unit HT.

A first current applying device CR1 may come in contact with the first heating signal pad PD-H1 through the first through-hole CT-1 exposing the first heating signal pad PD-H1. A second current applying device CR2 may come in contact with the second heating signal pad PD-H2 through the second through-hole CT-2 exposing the second heating signal pad PD-H2.

The first current applying device CR1 and the second current applying device CR2 may be independently controlled. For example, the current value applied to the first heating signal pad PD-H1 by the first current applying device CR1 may be different from the current value applied to the second heating signal pad PD-H2 by the second current applying device CR2. However, the current values applied through the first and second current applying devices CR1 and CR2 may vary according to the heating temperature to be implemented through the heating unit HT, and the disclosure is not limited to any one embodiment.

The first conductive pattern CP1c having a predetermined or selected resistance may be heated by the current applied to the first heating signal pad PD-H1. The second conductive pattern CP2c having a predetermined or selected resistance may also be heated by the current applied to the second heating signal pad PD-H2. In an embodiment, the first conductive pattern CP1c and the second conductive pattern CP2c may come in contact with each other on a region overlapping the driving unit DIC. The first conductive pattern CP1c and the second conductive pattern CP2c may contain different materials, and contact resistance may occur at the contact portion between the first conductive pattern CP1c and the second conductive pattern CP2c. Accordingly, heat may be effectively generated in the contact region between the first conductive pattern CP1c and the second conductive pattern CP2c, and the conductive adhesive member AF may be heated.

In the method of manufacturing the display module according to an embodiment, as the conductive adhesive member AF is heated by the heating unit HT disposed inside the display module, a region requiring heat may be locally and intensively heated, thereby preventing the configuration of the input sensing unit ISP or the anti-reflection layer RPP disposed adjacent to the driving unit bonding region DIC-B from being damaged.

The resistance value of the heating unit HT may vary depending on the material included in the conductive patterns CP1c and CP2c of the heating unit HT or the shape thereof, and the heating temperature thereof may be precisely and uniformly controlled by adjusting the configuration of the heating unit HT or the current applied to the heating unit HT. Through this technique, the conductive adhesive member AF may be uniformly heated.

In case that the display module DM (see FIG. 7) does not include the heating unit HT, the external bonding device BD should provide high-temperature heat to heat the conductive adhesive member AF. For example, a temperature of about 150 degrees (° C.) to about 200 degrees (° C.) may be required to adhere the conductive adhesive member AF to the driving unit DIC and the signal pads PD, and in order to satisfy the corresponding condition, the external bonding device BD may provide heat of about 300 degrees (° C.) or more. In case that the external bonding device BD provides high-temperature heat because the heating unit HT is not included, the input sensing unit ISP or the anti-reflection layer RPP disposed adjacent to the high-temperature external bonding device BD may be damaged. For example, the polarizing film of the anti-reflection layer RPP may be burned by the high-temperature external bonding device BD.

In case that the heating unit HT is not included, the driving unit bonding region DIC-B and the display element layer DP-OL, the input sensing unit ISP, and the anti-reflection layer RPP should be designed to be spaced apart from each other by a certain area or more in order to prevent the display module from being damaged by the high-temperature external bonding device BD. A problem may occur in which the area of the bezel region BZA (see FIG. 1) of the electronic device ED (see FIG. 1) is enlarged because the area of the non-display region NDA (see FIG. 3A) of the display module DM (see FIG. 3A) is enlarged.

However, as the display module DM (see FIG. 7) includes the heating unit HT and the driving unit bonding region DIC-B is heated by the heating unit HT, a heating step by using the external bonding device BD may be omitted, or the temperature of the heat provided by the external bonding device BD may be lowered. As the heating unit HT may locally heat a region, it is possible to prevent the input sensing unit ISP and the anti-reflection layer RPP of the display module DM (see FIG. 7) from being heated and damaged without enlarging the area of the non-display region NDA (see FIG. 3A).

The base resin portion AF-R of the heated conductive adhesive member AF may have fluidity, and the conductive particles AF-B dispersed in the base resin portion AF-R may flow in the base resin portion AF-R. Through this, the conductive particles AF-B may be positioned between the signal pads PD and the driving signal pads DC-P.

By applying pressure PR to the conductive adhesive member AF by the external bonding device BD, the direction in which a current flows through the conductive particles AF-B may have anisotropy. For example, the direction of a current passing through the conductive particles AF-B may be parallel to the pressing direction, and a current may not flow in a direction crossing the pressing direction. Accordingly, while preventing a short circuit from occurring between adjacent signal pads PD or between adjacent driving signal pads DC-P, the signal pads PD and the driving signal pads DC-P corresponding to each other may be electrically connected to each other.

By applying heat and pressure PR to the conductive adhesive member AF with the use of the heating unit HT and the external bonding device BD, the driving unit DIC may be bonded to the driving unit bonding region DIC-B, and the display module DM to which the driving unit DIC is bonded may correspond to the display module DM illustrated in FIG. 7.

The process of bonding the driving unit DIC describes that heat is provided to the driving unit bonding region DIC-B by the heating unit HT, but the heating unit HT may also be used in the process of a rework in which the driving unit DIC or the flexible circuit board FCB is separated from the display module DM. A high-temperature environment may be required to separate the driving unit DIC or the flexible circuit board FCB from the display module DM, and the driving unit DIC or the flexible circuit board FCB may be easily reworked by heating the heating unit HT through the way of applying a current to the heating unit HT.

By including the heating unit, the display module according to an embodiment may locally heat a region in which heat is required in the process of bonding the driving unit and uniformly and precisely control the temperature in a region in which the driving unit is bonded. The temperature of the external bonding device which bonds the drive unit may be lowered by using the heating unit, and the components of the display module may be prevented from being damaged by a high-temperature external bonding device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display module comprising:
a base comprising a display region and a non-display region;
pixels disposed in the display region;
a driver disposed in the non-display region and electrically connected to the pixels to provide a driving signal;
signal pads disposed in the non-display region and electrically connected to the driver;
a heater overlapping the driver and disposed below the signal pads; and
a heating signal pad electrically connected to the heater.

2. The display module of claim 1, wherein
the heater comprises a first conductive pattern disposed on the base, and
the first conductive pattern comprises:
first line portions extending in a first direction; and
second line portions integrally connected to the first line portions on a same layer and extending in a second direction intersecting the first direction.

3. The display module of claim 2, wherein
the heater further comprises a second conductive pattern disposed on the first conductive pattern, and
the second conductive pattern comprises:
third line portions extending in the first direction; and
fourth line portions integrally connected to the third line portions on a same layer and extending in the second direction.

4. The display module of claim 3, wherein the first conductive pattern and the second conductive pattern are electrically insulated from each other.

5. The display module of claim 1, wherein
the heater comprises:
a first conductive pattern disposed on the base and;
a second conductive pattern disposed on the first conductive pattern,
the first conductive pattern comprises:
a first pattern connected to the heating signal pad; and
a plurality of second patterns spaced apart from the first pattern,
the second conductive pattern comprises third patterns contacting adjacent second patterns among the plurality of second patterns and connecting the adjacent second patterns to each other.

6. The display module of claim 5, wherein the third patterns comprise a material different from that of the plurality of second patterns.

7. The display module of claim 1, wherein
the heating signal pad comprises:
a first heating signal pad; and
a second heating signal pad spaced apart from the first heating signal pad, the heater comprises:
a first conductive pattern connected to the first heating signal pad; and
a second conductive pattern connected to the second heating signal pad and disposed on the first conductive pattern.

8. The display module of claim 7, wherein
the first conductive pattern comprises a first planar portion overlapping the signal pads, and
the second conductive pattern comprises a second planar portion contacting the first planar portion.

9. The display module of claim 8, wherein the first planar portion and the second planar portion comprise different materials from each other.

10. The display module of claim 9, wherein
pattern openings passing through the second conductive pattern are defined in the second planar portion, and
the pattern openings are disposed in a direction.

11. The display module of claim 7, wherein the first heating signal pad and the second heating signal pad are disposed on different layers.

12. The display module of claim 7, wherein each of the first heating signal pad and the second heating signal pad is disposed on a layer different from that of the signal pads.

13. The display module of claim 1, wherein
the base comprises a base layer that provides a base surface on which the heater and the signal pads are disposed, and
a portion of the base layer, which corresponds to a region between the display region and the driver in a plan view, is bent with respect to a bending axis.

14. The display module of claim 1, wherein:
the base comprises:
a base layer that provides a base surface, on which the pixels are disposed; and
a flexible circuit board disposed on the base layer,
the driver, the signal pads, the heater, and the heating signal pad are disposed on the flexible circuit board, and
the flexible circuit board is bent toward a rear surface of the base layer.

15. The display module of claim 1, wherein
each of the pixels comprise:
a transistor comprising a gate electrode;
an upper electrode overlapping the gate electrode;
a light-emitting element electrically connected to the transistor; and
a connection electrode electrically connecting the transistor and the light-emitting element to each other, and
the heater comprises a conductive pattern disposed on the same layer as at least one of the gate electrode, the upper electrode, and the connection electrode.

16. The display module of claim 1, further comprising:
a conductive adhesive member disposed between the signal pads and the driver to electrically connect the signal pads and the driver to each other.

17. A display module comprising:
a base layer comprising a display region and a driver bonding region spaced apart from the display region;
pixels disposed on the display region;
signal lines electrically connected to the pixels and extending from the display region toward the driver bonding region;
signal pads disposed on the driver bonding region and electrically connected to the signal lines;
a heater overlapping the signal pads; and
a heating signal pad electrically connected to the heater,
wherein the heating signal pad and the signal pads are electrically insulated from each other.

18. The display module of claim 17, further comprising:
connection pads spaced apart from the driver bonding region in a first direction and respectively connected to corresponding signal pads among the signal pads,
wherein the heating signal pad and the connection pads are disposed in a second direction intersecting the first direction.

19. A method for manufacturing a display module, the method comprising:
providing the display module comprising a heater, a heating signal pad electrically connected to the heater, and signal pads disposed on the heater and spaced apart from the heating signal pad;
providing a conductive adhesive member on the signal pads;
providing a driver on the conductive adhesive member; and
heating the conductive adhesive member to electrically connect the signal pads and the driver to each other,
wherein the heating of the conductive adhesive member comprises applying a current to the heating signal pad to heat the heater.

20. The method of claim 19, wherein the electrical connection of the signal pads to the driver further comprises providing an external bonding device on the driver to apply pressure to the conductive adhesive member.
